(19) United States
(12) Patent Application Publication
(10) Pub. No.: US 2026/0107442 A1
(43) Pub. Date: Apr. 16, 2026

(54) SEMICONDUCTOR DEVICE AND ARITHMETIC DEVICE

(71) Applicant: SEMICONDUCTOR ENERGY LABORATORY CO., LTD., Atsugi-shi, Kanagawa-ken (JP)

(72) Inventors: Yoshiyuki KUROKAWA, Sagamihara, Kanagawa (JP); Takanori MATSUZAKI, Atsugi, Kanagawa (JP); Hidetomo KOBAYASHI, Isehara, Kanagawa (JP)

(21) Appl. No.: 19/116,438

(22) PCT Filed: Oct. 2, 2023
(86) PCT No.: PCT/IB2023/059839

§ 371 Date: Mar. 28, 2025

(30) Foreign Application Priority Data
Oct. 7, 2022 (JP) 2022-162337

(51) Int. Cl. H10B 12/00; G11C 11/4076; H10D 1/68; H10D 30/67

(52) U.S. Cl. CPC H10B 12/33; G11C 11/4076; H10D 1/716; H10D 30/6728; H10D 30/6731

(57) ABSTRACT

A semiconductor device including a flip-flop circuit and a memory circuit is provided. The memory circuit includes a first transistor, a second transistor, a first capacitor, and a second capacitor. The semiconductor device includes a substrate, a first insulator, and a second insulator. The first insulator includes a first opening and a second opening. The second insulator includes a third opening and a fourth opening. The flip-flop circuit is provided over the substrate. At least parts of the first capacitor and the second capacitor are provided in the first opening portion and the second opening portion, respectively. At least parts of the first transistor and the second transistor are provided in the third opening portion and the fourth opening portion, respectively.

### TECHNICAL FIELD

One embodiment of the present invention relates to a semiconductor device and an arithmetic device.

Note that one embodiment of the present invention is not limited to the above technical field. The technical field of one embodiment of the invention disclosed in this specification and the like relates to an object, a method, a driving method, or a manufacturing method. One embodiment of the present invention relates to a process, a machine, manufacture, or a composition of matter. Specific examples of the technical field of one embodiment of the present invention disclosed in this specification and the like include a semiconductor device, a display apparatus, a light-emitting apparatus, a power storage device, an optical device, an image capturing device, a lighting device, an arithmetic device, a control device, a memory device, an input device, an output device, an input/output device, a signal processing device, an arithmetic processing device, an electronic computer, an electronic device, driving methods thereof, and manufacturing methods thereof.

### BACKGROUND ART

The technical development of a semiconductor device that includes a transistor (hereinafter an OS transistor) including an oxide semiconductor in a channel formation region and is capable of retaining charge corresponding to data has progressed.

For example, the semiconductor device can achieve low power consumption owing to power gating or the like by having a structure of performing saving (storing or backing up) or loading (restoring or recovering) of a program or data retained into a flip-flop or the like. Thus, the application to a CPU (Central Processing Unit) or the like is progressing (see Patent Document 1, for example).

In the CPU or the like, a series of processes (task) is executed by sequentially executing a process corresponding to a program or data.

In the case where a plurality of tasks are executed, each of the tasks is divided into small processing units and the processing units of each task are sequentially executed, so that it looks as if the plurality of tasks is executed at the same time. In order to execute such process, a plurality of register banks (sets of general registers) capable of retaining a state (also referred to as context) of the CPU or the like at the time of executing each task are prepared, and a plurality of tasks are executed by sequentially switching to a register bank corresponding to each task.

Also in the case where a shift of a program from a main routine to a subroutine is performed, a process of the subroutine is executed after the register bank is switched and a process of the main routine is executed after the process of the subroutine is finished and the register bank is switched to the original register bank.

### REFERENCE

### Patent Document

[Patent Document 1]Japanese Published Patent Application No. 2013-9297

### SUMMARY OF THE INVENTION

### Problems to be Solved by the Invention

In the CPU or the like, in switching tasks, a process is stopped after data of a task being executed is saved to a corresponding register bank, and the process is restarted after data of a task to be executed next is loaded from a corresponding register bank. However, when a register bank lacks in processing of a complicated process, data in a register corresponding to the task is temporarily written to an external memory, and in the case where the task is executed again, the data needs to be written back from the external memory to the register. In this case, energy is consumed for writing and writing back of data between the external memory and the register. Preparing a large number of register banks can inhibit energy consumption due to writing and writing back of data between the external memory and the register but leads to an increase in circuit layout area.

An object of one embodiment of the present invention is to provide a novel semiconductor device or the like. Another object of one embodiment of the present invention is to provide a semiconductor device or the like with a novel structure that can inhibit an increase in circuit layout area. Another object of one embodiment of the present invention is to provide a semiconductor device or the like with a novel structure that is excellent in reducing power consumption. Another object of one embodiment of the present invention is to provide a semiconductor device or the like with a novel structure that is excellent in computing performance.

Note that the above objects do not preclude the existence of other objects. One embodiment of the present invention does not need to achieve the above objects. Objects other than the objects are apparent from the description of the specification, the drawings, the claims, and the like and objects other than the objects can be derived from the description of the specification, the drawings, the claims, and the like.

### Means for Solving the Problems

One embodiment of the present invention has been made in view of the above objects, and a plurality of memories each including an OS transistor and a capacitor (also referred to as OS memories) are provided to be stacked over a register in a CPU or the like, and a function of writing and writing back data to and from a register in response to a plurality of tasks is included. At the time of switching tasks, data of a register corresponding to a first task is written to a first OS memory, and data of a second OS memory corresponding to a second task to be the next task is written back to a register, for example. In the OS memory, the OS transistor is stacked over the capacitor, and part of a dielectric layer of the capacitor and part of a semiconductor layer including a channel formation region of the OS transistor are provided in a direction perpendicular to a plane of a substrate provided with a register, whereby the memory capacity per unit area can be increased.

### (1)

One embodiment of the present invention is a semiconductor device including a flip-flop circuit and a memory circuit. The memory circuit includes a first transistor, a second transistor, a first capacitor, and a second capacitor. One of a source and a drain of the first transistor is electrically connected to one of a source and a drain of the second transistor, one terminal of the first capacitor, and one terminal of the second capacitor. The other of the source and the drain of the first transistor is electrically connected to an output terminal of the flip-flop circuit. The other of the source and the drain of the second transistor is electrically connected to an input terminal of the flip-flop circuit. A substrate, a first insulator, and a second insulator are included. The first insulator is provided over the substrate. The second insulator is provided over the first insulator. The first insulator includes a first opening portion and a second opening portion that are provided to extend in a direction perpendicular to a plane of the substrate. The second insulator includes a third opening portion and a fourth opening portion that are provided to extend in the direction perpendicular to the plane of the substrate. The flip-flop circuit is provided over the substrate. At least parts of the first capacitor and the second capacitor are provided in the first opening portion and the second opening portion, respectively. At least parts of the first transistor and the second transistor are provided in the third opening portion and the fourth opening portion, respectively.

### (2)

In the above (1), at least parts of dielectric layers of the first capacitor and the second capacitor are provided along sidewalls of the first opening portion and the second opening portion, respectively. At least parts of semiconductor layers including channel formation regions of the first transistor and the second transistor are provided along sidewalls of the third opening portion and the fourth opening portion, respectively.

### (3)

In the above (2), the semiconductor layer preferably contains an oxide semiconductor.

### (4)

One embodiment of the present invention is an arithmetic device including the semiconductor device according to any one of the above (1) to the above (3) and a control portion. The control portion has a function of generating a signal for controlling an operation of the semiconductor device. The semiconductor device has a function of saving data retained in the flip-flop circuit to the memory circuit by controlling a conduction state or a non-conduction state of the first transistor and a function of loading data retained in the memory circuit into the flip-flop circuit by controlling a conduction state or a non-conduction state of the second transistor.

### (5)

In the above (4), the semiconductor device preferably includes a plurality of the memory circuits. The semiconductor device preferably has a function of, when tasks are switched, saving first data retained in the flip-flop circuit to any one of the plurality of the memory circuits and loading second data retained in any one of the plurality of the memory circuits into the flip-flop circuit.

### Effect of the Invention

One embodiment of the present invention can provide a novel semiconductor device or the like. Another embodiment of the present invention can provide a semiconductor device or the like with a novel structure that can inhibit an increase in circuit layout area. Another embodiment of the present invention can provide a semiconductor device or the like with a novel structure that is excellent in reducing power consumption. Another embodiment of the present invention can provide a semiconductor device or the like with a novel structure that is excellent in computing performance.

Note that the descriptions of the above effects do not preclude the existence of other effects. Note that one embodiment of the present invention does not need to have all the effects listed above. Effects other than the effects listed above are apparent from the description of the specification, the drawings, the claims, and the like and effects other than the effects listed above can be derived from the description of the specification, the drawings, the claims, and the like.

### BRIEF DESCRIPTION OF THE DRAWINGS

FIG. 1A is a circuit diagram illustrating a structure example of a semiconductor device. FIG. 1B is a schematic diagram illustrating the structure example of the semiconductor device.

FIG. 2A is a schematic diagram illustrating an operation example of the semiconductor device.

FIG. 2B is a timing chart showing the operation example of the semiconductor device.

FIG. 3A to FIG. 3E are schematic diagrams each illustrating an operation example of the semiconductor device.

FIG. 4 is a schematic diagram illustrating a structure example of an arithmetic device.

FIG. 5 is a schematic diagram illustrating an operation example of the arithmetic device.

FIG. 6 is a diagram illustrating a structure example of the semiconductor device.

FIG. 7 is a diagram illustrating a structure example of the semiconductor device.

FIG. 8A to FIG. 8C are diagrams illustrating structure examples of the semiconductor device.

FIG. 9A and FIG. 9B are diagrams each illustrating a structure example of the semiconductor device.

FIG. 10 is a diagram illustrating a structure example of a semiconductor device.

FIG. 11A and FIG. 11B are diagrams illustrating a structure example of the semiconductor device.

FIG. 12A and FIG. 12B are diagrams illustrating examples of electronic components.

FIG. 13A and FIG. 13B are diagrams illustrating examples of electronic devices. FIG. 13C to

FIG. 13E are diagrams illustrating examples of a large computer.

FIG. 14 is a diagram illustrating an example of a device for space.

FIG. 15 is a diagram illustrating an example of a storage system that can be used in a data center.

### MODE FOR CARRYING OUT THE INVENTION

In this specification and the like, a semiconductor device refers to a device that utilizes semiconductor characteristics, and means a circuit including a semiconductor element (e.g., a transistor or a diode) or a device including the circuit, for example. The semiconductor device also means all devices that can function by utilizing semiconductor characteristics. For example, an integrated circuit including a semiconductor element, a chip provided with an integrated circuit, an electronic component including a packaged chip, and an electronic device provided with an electronic component are examples of a semiconductor device. For example, a display apparatus, a light-emitting apparatus, a power storage device, an optical device, an image capturing device, a lighting device, an arithmetic device, a control device, a memory device, an input device, an output device, an input/output device, a signal processing device, an electronic computer, an electronic device, and the like themselves might be semiconductor devices, or might include semiconductor devices.

Embodiments will be described below with reference to the drawings. Note that the embodiments can be implemented in many different modes. Thus, it will be readily understood by those skilled in the art that the modes and details can be changed in various ways without departing from the spirit and scope thereof. Therefore, one embodiment of the present invention should not be interpreted as being limited to the description in the embodiments.

In this specification and the like, one embodiment of the present invention can be constituted by appropriately combining a structure described in an embodiment with any of the structures described in the other embodiments. In addition, in the case where a plurality of structures are described in one embodiment, the structures can be combined with each other as appropriate to constitute one embodiment of the present invention.

As for the drawings illustrating the embodiments, in the structures of the invention, the same reference numerals are used in common for the same portions or portions having similar functions in different drawings, and repeated description thereof is omitted in some cases. Furthermore, for example, the same hatching pattern is used for the portions having similar functions throughout the drawings, and the portions are not especially denoted by reference numerals in some cases. Moreover, some components are omitted in a perspective view or a top view (also referred to as a “plan view”), and the like for easy understanding of the drawings in some cases. The description of, for example, some hidden lines might also be omitted in the drawings. In the drawings, for example, a hatching pattern or the like may be omitted.

In the drawings, the size, the layer thickness, or the region is sometimes exaggerated for clarity. Thus, the drawings are not limited to the drawings with the illustrated size, aspect ratio, and the like, for example. Note that the drawings schematically illustrate ideal examples, and embodiments of the present invention are not limited to shapes, values, and the like illustrated in the drawings, for example. For example, in the actual manufacturing process, a layer, a resist mask, or the like might be unintentionally reduced in size by treatment such as etching, which might not be reflected in the drawings for easy understanding. For example, in the actual circuit operation, a fluctuation in voltage, current, or the like might be caused by noise, difference in timing, or the like, which is not illustrated in some cases for easy understanding.

In this specification, the drawings, and the like, components are classified on the basis of the functions, and shown as components independent of one another in some cases. However, such components are sometimes hard to classify functionally, and there is a case where one component is associated with a plurality of functions and a case where a plurality of components are associated with one function. Accordingly, the component is not limited to that described in this specification, drawings, and the like and can be explained with another term as appropriate depending on the situation.

In this specification, the drawings, and the like, when a plurality of components are denoted by the same reference numerals, and in particular need to be distinguished from each other, an identification sign such as “A”, “b”, “_1”, “[n]”, or “[m, n]” is sometimes added to the reference numerals, for example. When matters common to a plurality of components with identification signs are described or they do not need to be distinguished from each other, the identification signs are not added in the description in some cases.

Note that in this specification and the like, a “conduction state” or “on state” of a transistor refers to a state where a source and a drain of the transistor can be regarded as being electrically short-circuited or a state where current can be made to flow between the source and the drain, for example. For example, the “conduction state” or the “on state” refers to a state where the voltage between the gate and the source is higher than the threshold voltage in an n-channel transistor, a state where the voltage between the gate and the source is lower than the threshold voltage in a p-channel transistor, or the like in some cases. Furthermore, a “non-conduction state”, a “cutoff state”, or an “off state” of the transistor refers to a state where the source and the drain of the transistor can be regarded as being electrically disconnected. For example, the “non-conduction state”, the “cutoff state”, or the “off state” refers to a state where the voltage between the gate and the source is lower than the threshold voltage in an n-channel transistor, a state where the voltage between the gate and the source is higher than the threshold voltage in a p-channel transistor, or the like in some cases.

In this specification and the like, “gate voltage” refers to the voltage between a gate and a source, “drain voltage” refers to the voltage between a drain and a source, and “back gate voltage” refers to the voltage between a back gate and a source in some cases. In addition, “drain current” refers to current flowing between the drain and the source in some cases. The description of “high gate voltage,” “high drain voltage,” “high back gate voltage,” and the like of an n-channel transistor can be replaced with the description of “low gate voltage,” “low drain voltage,” “low back gate voltage,” and the like of a p-channel transistor, respectively, as appropriate. The description of “low gate voltage,” “low drain voltage,” “low back gate voltage,” and the like of an n-channel transistor can be replaced with the description of “high gate voltage,” “high drain voltage,” “high back gate voltage,” and the like of a p-channel transistor, respectively, as appropriate.

In this specification and the like, “off-state current” of a transistor refers to drain current of the transistor in an off state unless otherwise specified. Note that in this specification and the like, off-state current and current flowing between a gate and a source or a drain (also referred to as gate leakage current) are sometimes referred to as leakage current.

### Embodiment 1

A semiconductor device of one embodiment of the present invention will be described with reference to drawings. Note that the semiconductor device of one embodiment of the present invention may be used as part of a register included in an arithmetic processing device such as a CPU (Central Processing Unit), an MPU (Micro Processing Unit), or an MCU (Micro Controller Unit), for example.

### Structure Example of Register

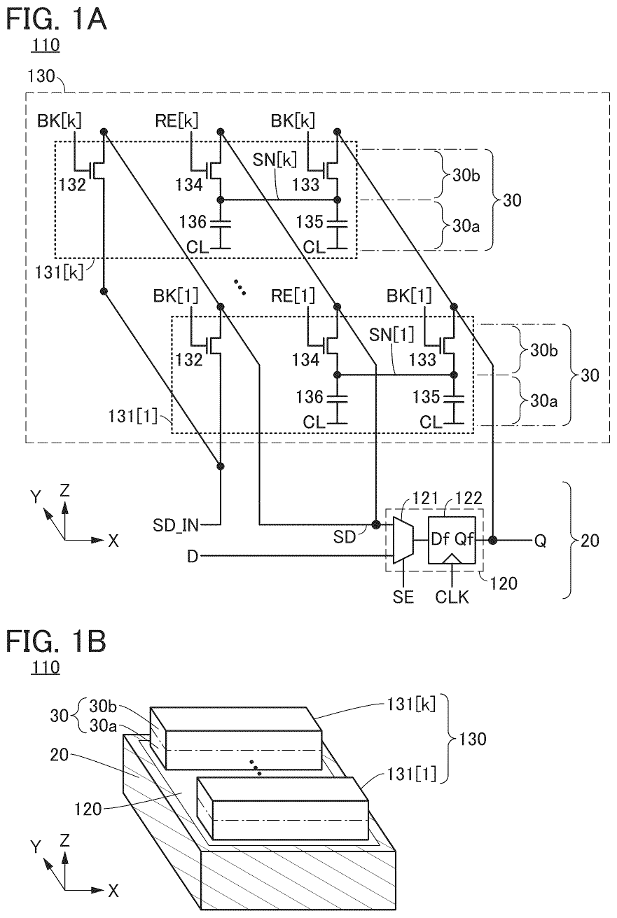

FIG. 1A and FIG. 1B are schematic diagrams illustrating a structure example of a register of one embodiment of the present invention.

A register 110 illustrated in FIG. 1A and FIG. 1B includes a scan flip-flop 120 (volatile register) and a data retention circuit 130. The scan flip-flop 120 includes a selector 121 and a flip-flop 122. The data retention circuit 130 includes a memory circuit 131[1] to a memory circuit 131[k] (k is an integer greater than or equal to 2). Each of the memory circuit 131[1] to the memory circuit 131[k] includes a transistor 132, a transistor 133, a transistor 134, a capacitor 135, and a capacitor 136.

Note that in FIG. 1A and FIG. 1B, the X direction, the Y direction, and the Z direction are defined for easy understanding of the description of the positional relationship between components that constitute the register 110. In FIG. 1A and FIG. 1B, the Z direction is a direction perpendicular to a plane of a substrate where the register 110 is provided. In this specification and the like, “perpendicular” indicates a state where the angle formed between two elements to be subjected is greater than or equal to 85° and less than or equal to 95°. In this specification and the like, the Z direction is sometimes referred to as a perpendicular direction for easy understanding. Note that the plane of the substrate where the register 110 is provided corresponds to a plane formed in the X direction, which is defined as the direction perpendicular to the Z direction, and the Y direction, which is defined as the direction perpendicular to both the X direction and the Z direction.

The scan flip-flop 120 can be provided in an element layer 20. The element layer 20 is provided over a substrate containing silicon, for example. Thus, the scan flip-flop 120 can be formed using a Si transistor (a transistor containing silicon in a channel formation region), for example.

The data retention circuit 130 is provided in an element layer 30 stacked in the perpendicular direction (Z direction) over the element layer 20. The element layer 30 includes an element layer 30a and an element layer 30b stacked in the perpendicular direction (Z direction) over the element layer 30a. The element layer 30a is provided with a capacitor. That is, the capacitor 135 and the capacitor 136 included in the data retention circuit 130 are provided. The element layer 30b is provided with a transistor. That is, the transistor 132, the transistor 133, and the transistor 134 included in the data retention circuit 130 are provided.

Part of a dielectric layer of the capacitor provided in the element layer 30a and part of a semiconductor layer including a channel formation region of the transistor provided in the element layer 30b are each provided to extend in the direction perpendicular to the plane of the substrate provided with the element layer 20 (the Z direction). Accordingly, the layout area of the memory circuit 131[1] to the memory circuit 131[k] can be reduced.

The transistor provided in the element layer 30b is an OS transistor (a transistor containing an oxide semiconductor in a channel formation region), for example.

An OS transistor has a feature in that the off-state current is extremely low because the band gap of an oxide semiconductor where a channel is formed is greater than or equal to 2 eV. The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

The off-state current of an OS transistor hardly increases even in a high-temperature environment. Specifically, the off-state current hardly increases even at an environment temperature higher than or equal to room temperature and lower than or equal to 200° C. Furthermore, the on-state current of an OS transistor is unlikely to decrease even in a high-temperature environment. Meanwhile, the on-state current of a Si transistor decreases in a high-temperature environment. That is, an OS transistor has a higher on-state current than a Si transistor in a high-temperature environment. In an OS transistor, the ratio between on-state current and off-state current is large even at an environmental temperature higher than or equal to 125° C. and lower than or equal to 150° C.; thus, a favorable switching operation can be performed. Therefore, the semiconductor device including an OS transistor can operate stably and have high reliability even in a high-temperature environment.

Note that specific structure examples of the element layer 20 and the element layer 30 will be described later.

As illustrated in FIG. 1A, a variety of signals that control an operation of the register 110 (a signal BK[1] to a signal BK[k], a signal RE[1] to a signal RE[k], a signal SE, and a signal CLK) are supplied to the register 110.

Note that in this specification and the like, for example, each signal is either a high-level or low-level potential, and a high level is a potential higher than a low level. For example, a potential difference between a high level and a low level is preferably larger than the threshold voltage of a transistor to which each signal is supplied. Note that the high level and the low level may be different from signal to signal.

Note that in this specification and the like, a high level is expressed as “H” or “High”, and a low level is expressed as “L” or “Low” in some cases. In some cases, setting a signal to a high level is expressed as “a signal is set to “H”” or “a signal=“H” is set”, and setting a signal to a low level is expressed as “a signal is set to “L”” or “a signal=“L” is set”.

Each of the signal BK[1] to the signal BK[k] is a signal that controls saving (storing or backing up) of data retained in the flip-flop 122 in the scan flip-flop 120. By the data saving, the data retained in the flip-flop 122 is written to and then retained in any one of the memory circuit 131[1] to the memory circuit 131[k] in the data retention circuit 130.

Each of the signal RE[1] to the signal RE[k] is a signal that controls loading (restoring or recovering) of data retained in any one of the memory circuit 131[1] to the memory circuit 131[k] in the data retention circuit 130. By the data loading, the data retained in any one of the memory circuit 131[1] to the memory circuit 131[k] is written back to and then retained in the flip-flop 122 in the scan flip-flop 120.

The signal SE is a switching signal for selecting an output of the selector 121.

The signal CLK is a clock signal for operating the flip-flop 122.

The register 110 stores and retains data input from a terminal D or data input from a terminal SD in the flip-flop 122 in the scan flip-flop 120 in synchronization with the signal CLK, and outputs the data from a terminal Q. The data retained in the flip-flop 122 is saved from the terminal Q in any one of the memory circuit 131[1] to the memory circuit 131[k] in the data retention circuit 130 by controlling the signal BK[1] to the signal BK[k]. The data retained in any one of the memory circuit 131[1] to the memory circuit 131[k] is loaded from the terminal SD into the flip-flop 122 by controlling the signal RE[1] to the signal RE[k].

The selector 121 has a function of supplying a signal in the terminal D or the terminal SD to the flip-flop 122 by controlling the signal SE. The terminal D is a terminal to which data input from the outside of the register 110 is supplied. The terminal SD is a terminal to which the data retained in any one of the memory circuit 131[1] to the memory circuit 131[k] in the data retention circuit 130 or data input from a terminal SD_IN is supplied. The terminal SD_IN is a terminal to which data for a scan test is supplied.

For the flip-flop 122, a flip-flop circuit prepared in a standard circuit library can be employed. As the flip-flop 122, a positive edge-triggered D flip-flop can be used, for example. The flip-flop 122 can retain one piece of data by including a circuit such as an inverter loop, for example. The flip-flop 122 retains data in an input terminal Df and outputs the retained data to the terminal Q through an output terminal Qf in synchronization with the signal CLK.

The data retention circuit 130 can retain the state of the scan flip-flop 120 for each task, which is caused by switching a plurality of tasks, in each of the memory circuit 131[1] to the memory circuit 131[k] in a one-to-one correspondence. When data is saved to the data retention circuit 130, any one of the memory circuit 131[1] to the memory circuit 131[k] is selected by controlling the signal BK[1] to the signal BK[k]. When data is loaded into the data retention circuit 130, any one of the memory circuit 131[1] to the memory circuit 131[k] is selected by controlling the signal RE[1] to the signal RE[k].

As illustrated in FIG. 1A, the signal BK[1] to the signal BK[k] and the signal RE[1] to the signal RE[k] are supplied to the memory circuit 131[1] to the memory circuit 131[k], respectively, in a one-to-one correspondence.

Note that in this specification and the like, a matter common to each of the memory circuit 131[1] to the memory circuit 131[k] is sometimes described as a matter of the memory circuit 131. In that case, each of the signal BK[1] to the signal BK[k] is referred to as the signal BK, and each of the signal RE[1] to the signal RE[k] is referred to as the signal RE in some cases.

As illustrated in FIG. 1A, the memory circuit 131 is connected to the terminal Q and the terminal SD. In the memory circuit 131, a terminal (wiring) connected to the terminal Q serves as an input terminal and a terminal (wiring) connected to the terminal SD serves as an output terminal. That is, in the register 110, the output terminal Qf of the flip-flop 122 is electrically connected to the input terminal of the memory circuit 131, and the input terminal Df of the flip-flop 122 is electrically connected to the output terminal of the memory circuit 131 through the selector 121.

In the memory circuit 131, one of a source and a drain of the transistor 133 is electrically connected to one terminal of the capacitor 135. One of a source and a drain of the transistor 134 is electrically connected to one terminal of the capacitor 136. The one terminal of the capacitor 135 and the one terminal of the capacitor 136 are electrically connected to each other. A wiring CL is electrically connected to the other terminal of the capacitor 135 and the other terminal of the capacitor 136.

The other of the source and the drain of the transistor 133 is electrically connected to the input terminal (i.e., the terminal Q) of the memory circuit 131. The other of the source and the drain of the transistor 134 is electrically connected to the output terminal (i.e., the terminal SD) of the memory circuit 131.

One of a source and a drain of the transistor 132 is electrically connected to the terminal SD. The other of the source and the drain of the transistor 132 is electrically connected to the terminal SD_IN.

Note that in the memory circuit 131[1] to the memory circuit 131[k], a node (wiring) where the one terminal of the capacitor 135 and the one terminal of the capacitor 136 are electrically connected to each other is sometimes referred to as the node SN[1] to the node SN[k], respectively. In the case where a matter common to each of the memory circuit 131[1] to the memory circuit 131[k] is described, each of the node SN[1] to the node SN[k] is sometimes referred to as a node SN.

An OS transistor is preferably used as each of the transistor 132, the transistor 133, and the transistor 134. As described above, an OS transistor has an extremely low off-state current and the off-state current thereof hardly increases even in a high-temperature environment.

Thus, the memory circuit 131 can retain one piece of data in the node SN for a long period of time when the transistor 133 and the transistor 134 are each brought into an off state (a non-conduction state).

That is, the memory circuit 131 can be used as a nonvolatile memory. For example, data can be continuously retained even in a power gating state (a state where power is not supplied to the scan flip-flop 120).

For another structure example of the register 110, a structure where the transistor 132 is provided in the element layer 20 and a Si transistor is used therefor may be employed. One transistor 132 may be provided for a plurality of memory circuits 131.

The signal BK is supplied to a gate of the transistor 133 and a gate of the transistor 132. The signal BK is a signal for saving data retained in the flip-flop 122 to the memory circuit 131.

The transistor 133 and the transistor 132 are brought into a conduction state or a non-conduction state in accordance with the signal BK. For example, the transistor 133 and the transistor 132 are turned on when the signal BK=“H” is set or are turned off when the signal BK=“L” is set.

The signal RE is supplied to a gate of the transistor 134. The signal RE is a signal for loading data retained in the memory circuit 131 to the flip-flop 122.

The transistor 134 is turned on or off in accordance with the signal RE. For example, the transistor 134 is turned on when the signal RE=“H” is set or is turned off when the signal RE=“L” is set.

The selector 121 selects and outputs a signal of the terminal SD or the terminal D in accordance with the signal SE. For example, the selector 121 selects and outputs the signal of the terminal SD when the signal SE=“H” is set or selects and outputs the signal of the terminal D when the signal SE=“L” is set.

The memory circuit 131 can write the data retained in the flip-flop 122 to the node SN when the signal BK=“H” is set and the signal RE=“L” is set, for example. The memory circuit 131 can write the data retained in the node SN back to the flip-flop 122 by setting the signal BK=“L”, the signal RE=“H”, and the signal SE=“H”, for example.

In the data retention circuit 130, any one of the signal BK[1] to the signal BK[k] is set to “H” and all of the signal RE[1] to the signal RE[k] are set to “L”, whereby the data retained in the flip-flop 122 can be saved to any one of the memory circuit 131[1] to the memory circuit 131[k]. For example, when the signal BK[1]=“H” is set in a state where all of the signal RE[1] to the signal RE[k] are set to “L”, the data retained in the flip-flop 122 can be written to the node SN[1] of the memory circuit 131[1]. Similarly, when the signal BK[k]=“H” is set, the data retained in the flip-flop 122 can be written to the node SN[k] of the memory circuit 131[k].

In the data retention circuit 130, all of the signal BK[1] to the signal BK[k] are set to “L” and any one of the signal RE[1] to the signal RE[k] is set to “H”, whereby the data retained in any one of the memory circuit 131[1] to the memory circuit 131[k] can be loaded into the flip-flop 122. For example, when the signal RE[1]=“H” and the signal SE=“H” are set in a state where all of the signal BK[1] to the signal BK[k] are set to “L”, the data retained in the node SN[1] of the memory circuit 131[1] can be written back to the flip-flop 122. Similarly, when the signal RE[k]=“H” and the signal SE=“H” are set, the data retained in the node SN[k] of the memory circuit 131[k] can be written back to the flip-flop 122.

One embodiment of the present invention has a structure in which, in the register 110, the data retention circuit 130 including the plurality of memory circuits 131 is provided to be stacked over the scan flip-flop 120.

Thus, the distance of a wiring electrically connecting the scan flip-flop 120 and the data retention circuit 130 can be shortened to each other. Thus, the time required for charging and discharging the wiring and power required for charging and discharging can be reduced. That is, energy (access energy) necessary for data saving and data loading can be reduced.

In the register 110, the data retention circuit 130 can be provided without changing a circuit structure and layout of the scan flip-flop 120. That is, the data retention circuit 130 is a circuit that has very broad utility.

When the data retention circuit 130 is provided, parasitic capacitance due to the wiring, the transistor 133, and the like are added to the terminal Q; however, the parasitic capacitance is lower than parasitic capacitance due to another circuit connected to the terminal Q and does not affect the operation of the scan flip-flop 120. That is, the data retention circuit 130 is provided, the performance of the register 110 does not substantially decrease.

In the register 110, the layout area of the data retention circuit 130 is preferably smaller than the layout area of the scan flip-flop 120. Accordingly, the area overhead due to the placement of the data retention circuit 130 can be reduced, preferably zero.

One embodiment of the present invention has a structure in which a transistor is provided to be stacked over a capacitor in the memory circuit 131 provided to be stacked over the scan flip-flop 120. In addition, one embodiment of the present invention has a structure in which part of the dielectric layer of the capacitor and part of the semiconductor layer including the channel formation region of the transistor are provided in the direction perpendicular to a plane of the substrate where the scan flip-flop 120 is provided. Thus, the layout area of the memory circuit 131 can be reduced. Thus, in the register 110, the number (k) of memory circuits 131 that can be provided in the data retention circuit 130 can be increased without an increase in area overhead. That is, the memory capacity per unit area of the data retention circuit 130 can be increased while an increase in process cost is inhibited.

Note that in the register 110, a plurality of element layers 30 may be stacked and the data retention circuit 130 may be provided in each of the element layers 30 to further increase the number of memory circuits 131 that can be provided without increasing the area overhead.

### Operation Example of Register

Next, an operation of the register 110 is described.

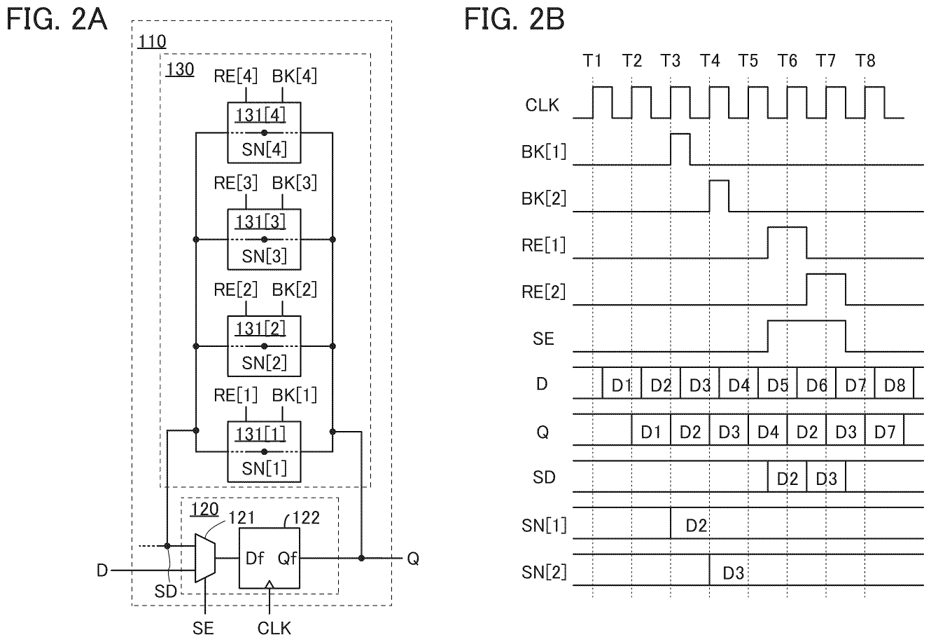

FIG. 2A illustrates a structure where the number of memory circuits 131 included in the data retention circuit 130 is four (k=4) as an example for describing the operation of the register 110. In FIG. 2A, the node SN[1] to the node SN[4] that retain data in the memory circuit 131[1] to the memory circuit 131[4] included in the data retention circuit 130 are illustrated. The signal BK[1] to the signal BK[4] and the signal RE[1] to the signal RE[4] that control the memory circuit 131[1] to the memory circuit 131[4] are illustrated.

FIG. 2B is a timing chart showing an operation example of the register 110 illustrated in FIG. 2A.

FIG. 2B illustrates the states (a high level (High) or a low level (Low)) of the signal CLK, the signal BK[1], the signal BK[2], the signal RE[1], the signal RE[2], and the signal SE in the period from Time T1 to Time T8 (the signal BK[3], the signal BK[4], the signal RE[3], and the signal RE[4] are not illustrated). In addition, the states of data (any one of data DI to data D8) supplied to each of the terminal D, the terminal Q, the terminal SD, the node SN[1], and the node SN[2] are illustrated (the node SN[3] and the node SN[4] are not illustrated).

In the period from Time T1 to Time T8, the flip-flop 122 stores data of the input terminal Df in synchronization with the timing at which the signal CLK is switched from “L” to “H” (a rising edge) and outputs the data from the output terminal Qf.

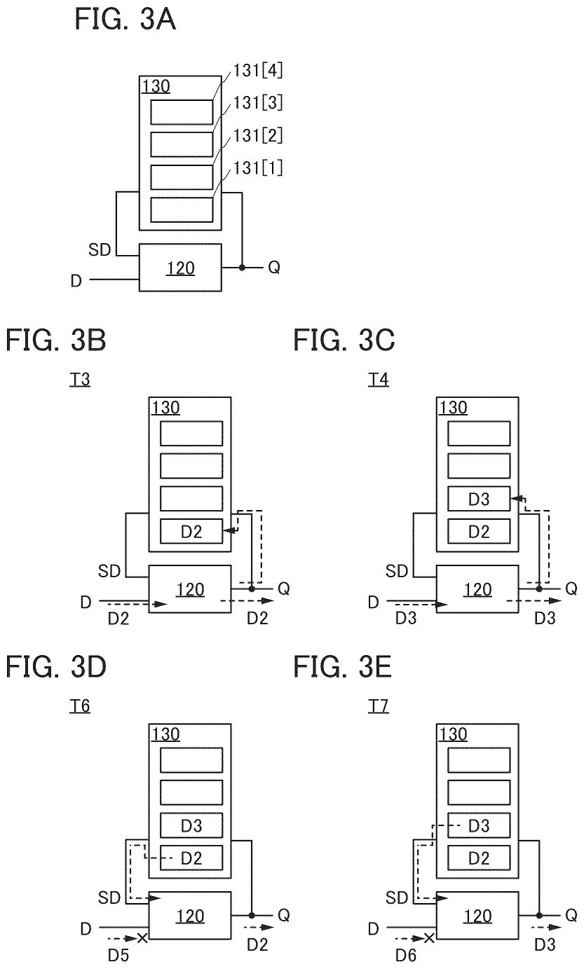

FIG. 3A to FIG. 3E are schematic diagrams for describing the state of the register 110 in the timing chart shown in FIG. 2B.

FIG. 3A illustrates the memory circuit 131[1] to the memory circuit 131[4] included in the data retention circuit 130 and the scan flip-flop 120. FIG. 3B, FIG. 3C, FIG. 3D, and FIG. 3E illustrate states where data is input to and output from the memory circuit 131[1] to the memory circuit 131[4] included in the data retention circuit 130 and the scan flip-flop 120 at Time T3, Time T4, Time T6, and Time T7 in the timing chart shown in FIG. 2B, respectively.

At Time T1, the signal BK[1] to the signal BK[4], the signal RE[1] to the signal RE[4], and the signal SE are each “L”. Furthermore, the states of the data supplied to the node SN[1] and the node SN[2] are undetermined (each of the data DI to the data D8 is not illustrated). The potential supplied to the wiring CL is a constant potential (e.g., a ground potential). Note that in the following description, in the case where the signals are not particularly specified, the state immediately before is maintained.

At Time T2, the data D1 supplied to the terminal D is stored in the scan flip-flop 120 and output to the terminal Q in synchronization with the rising edge of the signal CLK.

At Time T3, the data D2 supplied to the terminal D is stored in the scan flip-flop 120 and output to the terminal Q in synchronization with the rising edge of the signal CLK. Here, when the signal BK[1]=“H” is set, the data D2 output to the terminal Q is stored in the node SN[1] of the memory circuit 131[1] (see FIG. 3B).

Then, the signal BK[1]=“L” is set, whereby the data D2 stored in the node SN[1] is retained.

At Time T4, the data D3 supplied to the terminal D is stored in the scan flip-flop 120 and output to the terminal Q in synchronization with the rising edge of the signal CLK. Here, when the signal BK[2]=“H” is set, the data D3 output to the terminal Q is stored in the node SN[2] of the memory circuit 131[2] (see FIG. 3C).

Then, the signal BK[2]=“L” is set, whereby the data D3 stored in the node SN[2] is retained.

At Time T5, the data D4 supplied to the terminal D is stored in the scan flip-flop 120 and output to the terminal Q in synchronization with the rising edge of the signal CLK.

Then, the signal RE[1]=“H” is set, whereby the data D2 stored in the node SN[1] of the memory circuit 131[1] is supplied to the terminal SD. Although the data D5 is supplied to the terminal D, the terminal SD is selected when the signal SE=“H” is set.

At Time T6, the data D2 supplied to the terminal SD is stored in the scan flip-flop 120 and output to the terminal Q in synchronization with the rising edge of the signal CLK (see FIG. 3D).

Then, when the signal RE[1]=“L” and the signal RE[2]=“H” are set, whereby the data D3 stored in the node SN[2] of the memory circuit 131[2] is supplied to the terminal SD. Although the data D6 is supplied to the terminal D, the terminal SD is selected by setting the signal SE=“H”.

At Time T7, the data D3 supplied to the terminal SD is stored in the scan flip-flop 120 and output to the terminal Q in synchronization with the rising edge of the signal CLK (see FIG. 3E).

After that, the signal RE[2]=“L” and the signal SE=“L” are set.

At Time T8, the data D7 supplied to the terminal D is stored in the scan flip-flop 120 and output to the terminal Q in synchronization with the rising edge of the signal CLK.

As described above, the register 110 can perform the operation as described with reference to FIG. 2B and FIG. 3B to FIG. 3E.

One embodiment of the present invention can have a structure where the data of a task that is stopped is saved and the data of the task to be restarted is loaded in a CPU or the like using the register 110, for example. That is, in switching a plurality of tasks in the register 110, data in the scan flip-flop 120 can be written, retained, and written back to any one of the plurality of memory circuits 131.

### Structure Example of Arithmetic Device

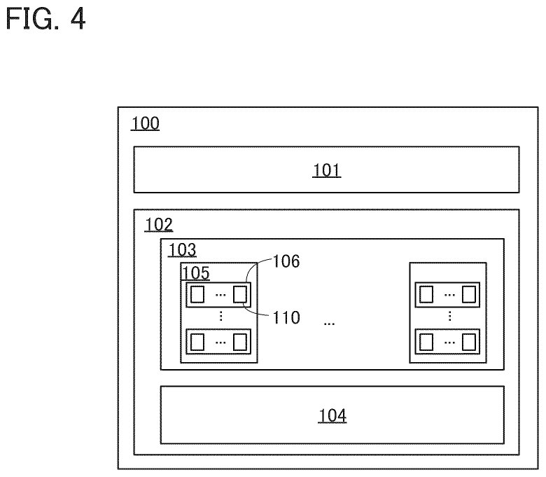

FIG. 4 is a block diagram illustrating a structure example of an arithmetic device including the register 110. The arithmetic device of one embodiment of the present invention may be used as part of a CPU or the like, for example.

An arithmetic device 100 illustrated in FIG. 4 includes a control portion 101 and a CPU core 102. The CPU core 102 includes a register portion 103 and an arithmetic portion 104. The register portion 103 includes a plurality of register banks 105. The register bank 105 includes a plurality of general registers 106. The general register 106 includes a plurality of registers 110.

In the arithmetic device 100, a series of processes (task) can be executed by sequentially executing a process corresponding to a program or data. The arithmetic device 100 can execute a plurality of tasks.

The control portion 101 has a function of outputting a control signal for performing switching between a plurality of tasks in accordance with a signal such as an interrupt signal (Interrupts) input from the outside of the arithmetic device 100 or a sleep signal generated by the CPU core 102, for example. For example, in switching a plurality of tasks, the control portion 101 has a function of generating a variety of signals that control the operation of the register 110 in the CPU core 102 (the signal BK[1] to the signal BK[k], the signal RE[1] to the signal RE[k], the signal SE, and the signal CLK) and supplying them to the register 110.

Note that the control portion 101 may have a function of outputting a signal for controlling power gating of the CPU core 102, for example.

The CPU core 102 has a function of performing arithmetic operation in the arithmetic portion 104 in accordance with program data retained in the register portion 103. The CPU core 102 is referred to as a processor core in some cases. The arithmetic device 100 may include one CPU core 102 (single-core) or two or more CPU cores (e.g., dual-core or multicore such as many-core).

The register portion 103 includes the register banks 105 provided in a pipeline register, a register file, and the like, for example. The register portion 103 has a function of temporarily retaining program data for performing arithmetic operation in the arithmetic portion 104, data used for the arithmetic operation, and data obtained by the arithmetic operation.

The arithmetic portion 104 has a function of performing a variety of arithmetic operations such as four arithmetic operations and logic operations in accordance with the program data retained in the register portion 103, for example. The arithmetic portion 104 is referred to as an ALU (Arithmetic logic unit) in some cases. The CPU core 102 may include a program counter or a control circuit in addition to the register portion 103 and the arithmetic portion 104, for example.

The register banks 105 are provided in accordance with a plurality of tasks executed by a process corresponding to program data. Each of the plurality of general registers 106 in the register bank 105 has a function of retaining program data for performing arithmetic operation, data used for the arithmetic operation, or data obtained by the arithmetic operation at the time of executing each task.

In the arithmetic device 100, the state (also referred to as context) of the arithmetic device 100 at the time of executing each task is retained in each register bank 105 provided for each task. In switching a plurality of tasks, the operation is controlled by the control portion 101 so that the register bank 105 is switched to correspond to each task.

That is, in switching the tasks, the arithmetic device 100 is controlled by the control portion 101 so that the context of the task being executed is saved (also referred to as stored or backed up) to the corresponding register bank 105, followed by stopping the process, and the context of the task to be executed next is loaded (also referred to as restored or recovered) from the corresponding register bank 105, followed by restarting the process. By executing a plurality of tasks while switching the register banks 105 in this manner, it is not necessary to perform data transmission for executing the tasks to and from a memory provided outside the arithmetic device 100 (e.g., a cache memory (e.g., an SRAM (Static Random Access Memory)) or a main memory (e.g., a DRAM (Dynamic Random Access Memory)) or the like). Accordingly, the operating speed of the arithmetic device 100 can be improved. That is, the computing performance of the arithmetic device 100 can be improved.

### Structure Example of Arithmetic Device

Next, an operation example of the register 110 accompanying with the switch of the task of the arithmetic device 100 is described.

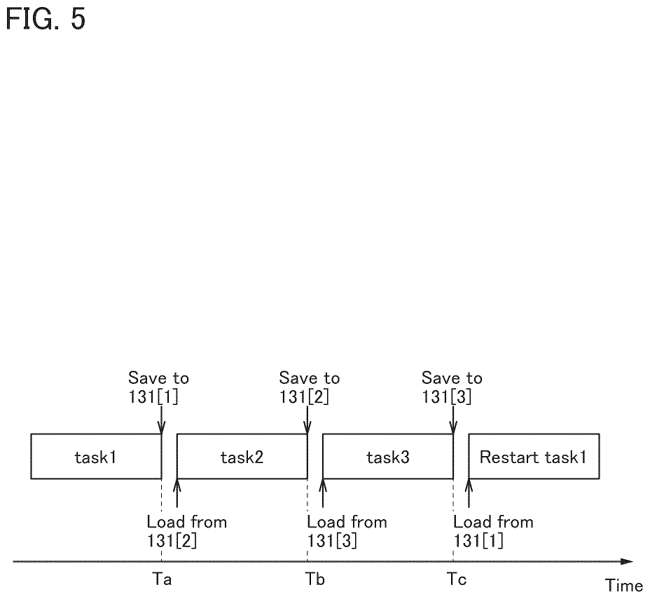

FIG. 5 is a schematic view illustrating an example of an operation of switching a plurality of tasks by using the register 110 illustrated in FIG. 2A in the arithmetic device 100 illustrated in FIG. 4 and performing the operation as described with reference to FIG. 2B.

FIG. 5 illustrates a state where three tasks, a task 1 (task1), a task 2 (task2), and a task 3 (task3), are sequentially switched and executed at respective time of Time Ta, Time Tb, and Time Tc. In addition, arrows indicate states where data for executing the task 1 to the task 3 are saved (Save) from the scan flip-flop 120 to the memory circuit 131[1] to the memory circuit 131[3], respectively, and states where data for executing the task 1 to the task 3 are loaded (Load) into the scan flip-flop 120 from the memory circuit 131[1] to the memory circuit 131[3], respectively. Note that the task 1 is executed immediately before Time Ta.

At Time Ta, the task 1 is stopped and the task 2 is started. That is, the data in the scan flip-flop 120 is saved to the memory circuit 131[1] in a state where the task 1 is being executed. After that, the data of the memory circuit 131[2] is loaded into the scan flip-flop 120, whereby the state can be switched to the state where the task 2 can be executed.

At Time Tb, the task 2 is stopped and the task 3 is started. That is, the data in the scan flip-flop 120 is saved to the memory circuit 131[2] in a state where the task 2 is being executed. After that, the data of the memory circuit 131[3] is loaded into the scan flip-flop 120, whereby the state can be switched to the state where the task 3 can be executed.

At Time Tc, the task 3 is stopped and the task 1 is restarted. That is, the data in the scan flip-flop 120 is saved to the memory circuit 131[3] in a state where the task 3 is being executed. After that, the data of the memory circuit 131[1] is loaded into the scan flip-flop 120, whereby the state can be switched to the state where the task 3 can be executed. Thus, the task 1 that has been stopped at Time Ta is restarted.

As described above, by performing the above-described operation, the arithmetic device 100 can restart the task that the task has been switched and stopped.

In one embodiment of the present invention, a large number of registers can be provided in a CPU or the like using the arithmetic device 100 and power consumption thereof can be reduced, for example. Since the process of the task can be restarted from where the task is stopped in switching the tasks, computing performance can be improved.

For example, even in the case where an operation such as an interruption by another task and an interruption by another task occurs while the task is being executed, data of a task of which a process is stopped by the interruption is retained, so that the process can be restarted from where the previous task is stopped. At this time, the data of the task of which the process is stopped by the interruption is retained in the register included in the arithmetic device. Thus, when data of the task is saved and loaded, it is not necessary to access a stack region of an external memory (e.g., an SRAM or a DRAM). Accordingly, even when switching of tasks due to interruption is performed, time lag caused by accessing an external memory does not occur; thus, interrupt processing can be performed efficiently.

### Structure Example of Element Layer

Next, a structure example of the element layer 20 and the element layer 30 (the element layer 30a and the element layer 30b) in which the register 110 is provided is described.

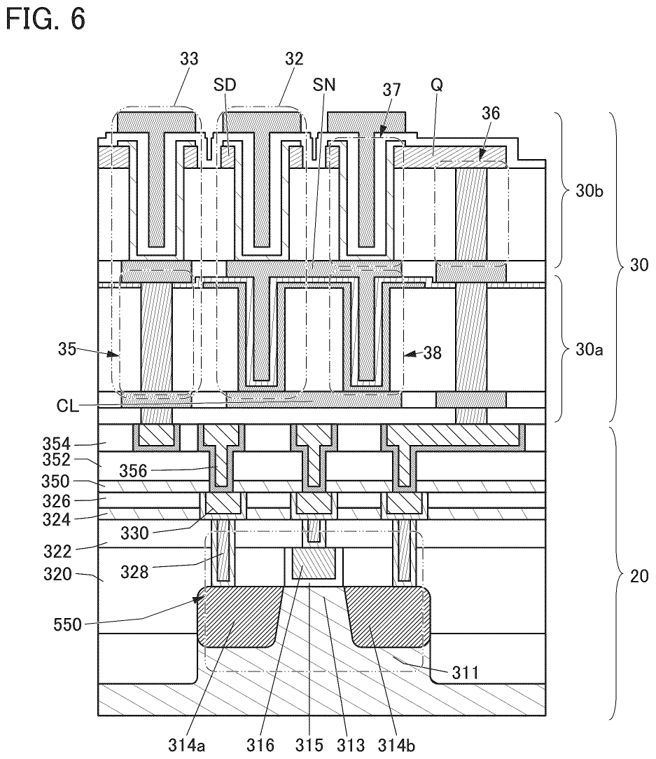

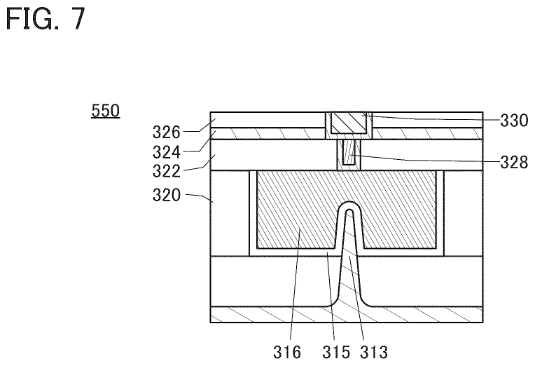

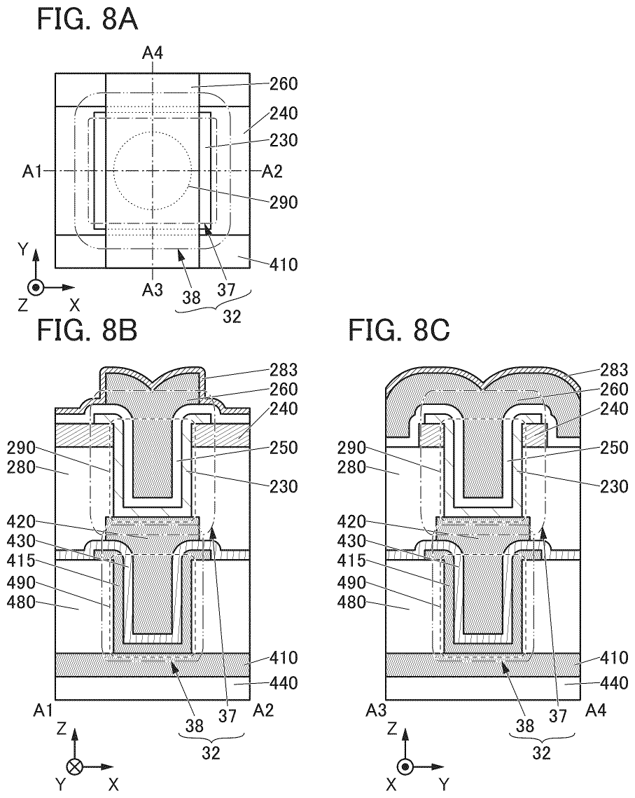

FIG. 6 illustrates part of a cross-sectional structure of a semiconductor device that can be used for the register 110. The semiconductor device illustrated in FIG. 6 includes a transistor 550, a transistor 37, a capacitor 38, a via hole 35, and a via hole 36. FIG. 7 is a cross-sectional view of the transistor 550 in the channel width direction. Note that FIG. 6 illustrates a cross-sectional view of the transistor 550 in the channel length direction. FIG. 8A is a top view of the transistor 37 and the capacitor 38, and FIG. 8B and FIG. 8C are cross-sectional views of the transistor 37 and the capacitor 38.

In FIG. 6, the transistor 550 corresponds to a Si transistor included in the element layer 20 (e.g., a transistor included in the scan flip-flop 120 in FIG. 1). The transistor 37 corresponds to an OS transistor included in the element layer 30b (e.g., the transistor 133 and the transistor 134 in FIG. 1). The capacitor 38 corresponds to a capacitor included in the element layer 30a (e.g., the capacitor 135 and the capacitor 136 in FIG. 1).

In FIG. 6, reference numerals of the terminal Q, the terminal SD, the node SN, and the wiring CL correspond to the terminal Q, the terminal SD, the node SN, and the wiring CL of the register 110 illustrated in FIG. 1, respectively.

As illustrated in FIG. 6, the transistor 37, the capacitor 38, the via hole 35, and the via hole 36 are provided above the transistor 550. The transistor 37 is provided over the capacitor 38 or over the via hole 35. The via hole 36 is provided over the via hole 35.

The via hole 35 is provided in the element layer 30a and formed using a conductor having a function as a plug or a wiring. The via hole 36 is provided in the element layer 30b and formed using a conductor having a function as a plug or a wiring. The transistor 37 can be electrically connected to the transistor 550 provided in the element layer 20 through the via hole 35 or through the via hole 36 and the via hole 35.

Note that in this specification and the like, the capacitor 38 and the transistor 37 provided over the capacitor 38 are collectively referred to as a memory cell 32 in some cases. The via hole 35 and the transistor 37 provided over the via hole 35 are collectively referred to as a functional element 33 in some cases. Thus, it can also be said that the semiconductor device illustrated in FIG. 6 includes two memory cells 32 and one functional element 33.

The transistor 37 and the capacitor 38 included in the memory cell 32 connected to the terminal Q in FIG. 6 correspond to the transistor 133 and the capacitor 135 illustrated in FIG. 1, respectively. The transistor 37 and the capacitor 38 included in the memory cell 32 connected to the terminal SD correspond to the transistor 134 and the capacitor 136 illustrated in FIG. 1, respectively. In FIG. 6, the transistor 37 included in the functional element 33 corresponds to the transistor 132 illustrated in FIG. 1.

In the memory cell 32, one of a source and a drain of the transistor 37 is electrically connected to one terminal of the capacitor 38. When the transistor 37 is brought into a non-conduction state, the memory cell 32 can retain charge accumulated in the capacitor 38. Thus, the memory cell 32 can store binary data when the potential corresponding to the amount of charge retained in the capacitor 38 is made to correspond to “1” or “0”, for example.

As illustrated in FIG. 6, in the two memory cells 32, terminals on one side (corresponding to the node SN) of the capacitors 38 are electrically connected to each other, and terminals on the other side (corresponding to the wiring CL) of the capacitors 38 are electrically connected to each other. Accordingly, the capacitance of a capacitor added to the node SN where charge is retained can be increased, and the data retention characteristics can be improved. In addition, miniaturization or high integration of a memory circuit including the two memory cells 32 (corresponding to the memory circuit 131 illustrated in FIG. 1) can be promoted.

### Transistor 550

The transistor 550 is provided on a substrate 311 and includes a conductor 316, an insulator 315, a semiconductor region 313 that is part of the substrate 311, a low-resistance region 314a functioning as one of a source region and a drain region, and a low-resistance region 314b functioning as the other of the source region and the drain region.

As illustrated in FIG. 7, in the transistor 550, the top surface and a side surface in the channel width direction of the semiconductor region 313 are covered with the conductor 316 with the insulator 315 therebetween. Such a Fin-type transistor 550 can have an increased effective channel width and thus have improved on-state characteristics of the transistor 550. In addition, contribution of the electric field of a gate electrode can be increased, so that the off-state characteristics of the transistor 550 can be improved.

Note that the transistor 550 may be either a p-channel transistor or an n-channel transistor. For example, by electrically connecting a gate of the n-channel transistor 550 and a gate of the p-channel transistor 550, a CMOS circuit (e.g., a circuit that operates complementarily, a CMOS logic gate, a CMOS logic circuit, or the like) can be formed.

The transistor 550 preferably contains a semiconductor such as a silicon-based semiconductor, further preferably contains single crystal silicon in a region of the semiconductor region 313 where a channel is formed, a region in the vicinity thereof, the low-resistance region 314a functioning as one of the source region and the drain region, the low-resistance region 314b functioning as the other of the source region and the drain region, and the like. Alternatively, the transistor 550 may be formed with a material containing Ge (germanium), SiGe (silicon germanium), GaAs (gallium arsenide), GaAlAs (gallium aluminum arsenide), or the like. For the transistor 550, a structure may be employed in which silicon whose effective mass is controlled by applying stress to the crystal lattice and thereby changing the lattice spacing. Alternatively, the transistor 550 may be an HEMT (High Electron Mobility Transistor) using GaAs and GaAlAs, for example.

The low-resistance region 314a and the low-resistance region 314b contain an element that imparts n-type conductivity, such as arsenic or phosphorus, or an element that imparts p-type conductivity, such as boron, for example, in addition to a semiconductor material used for the semiconductor region 313.

The conductor 316 functioning as a gate electrode can be formed using a semiconductor material such as silicon containing the element that imparts n-type conductivity, such as arsenic or phosphorus, or the element that imparts p-type conductivity, such as boron, for example. Alternatively, a conductive material such as a metal material, an alloy material, or a metal oxide material can be used, for example.

Note that since a work function depends on the material of the conductor, the threshold voltage of the transistor can be adjusted by selecting the material of the conductor. Specifically, a material such as titanium nitride or tantalum nitride is preferably used for the conductor, for example. Furthermore, in order to ensure both conductivity and embeddability, it is preferable to use stacked layers of metal materials such as tungsten and aluminum for the conductor, for example, and it is particularly preferable to use tungsten in terms of heat resistance.

The transistor 550 may be formed using an SOI (Silicon on Insulator) substrate or the like, for example.

As the SOI substrate, any of the following substrates may be used: a SIMOX (Separation by Implanted Oxygen) substrate formed in such a manner that an oxygen ion is implanted into a mirror-polished wafer, and then, an oxide layer is formed at a certain depth from the surface and defects generated in a surface layer are eliminated by high-temperature heating. Alternatively, an SOI substrate formed by a Smart-Cut method in which a semiconductor substrate is cleaved by utilizing growth of a minute void, which is formed by implantation of a hydrogen ion, by heat treatment or an ELTRAN method (registered trademark: Epitaxial Layer Transfer) may be used, for example. Note that a transistor formed using a single crystal substrate contains a single crystal semiconductor in a channel formation region.

An insulator 320, an insulator 322, an insulator 324, and an insulator 326 are sequentially stacked and provided to cover the transistor 550.

The insulator 320, the insulator 322, the insulator 324, and the insulator 326 are formed using, for example, silicon oxide, silicon oxynitride, silicon nitride oxide, silicon nitride, aluminum oxide, aluminum oxynitride, aluminum nitride oxide, or aluminum nitride.

Note that in this specification and the like, silicon oxynitride refers to a material that has a higher oxygen content than a nitrogen content, and silicon nitride oxide refers to a material that has a higher nitrogen content than an oxygen content. Moreover, in this specification and the like, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by the transistor 550 or the like provided below the insulator 322. For example, the top surface of the insulator 322 may be planarized by planarization treatment using a chemical mechanical polishing (CMP) method or the like to have improved planarity.

For example, the insulator 324 is preferably formed using a film having a barrier property that prevents hydrogen, impurities, or the like from diffusing from the substrate 311, the transistor 550, or the like into a region where the transistor 37 is provided.

For the film having a barrier property against hydrogen, for example, silicon nitride deposited by a CVD method can be used. For example, diffusion of hydrogen into a semiconductor element including an oxide semiconductor, such as the transistor 37, degrades the characteristics of the semiconductor element in some cases. Thus, a film that inhibits hydrogen diffusion is preferably provided between the transistor 37 and the transistor 550. The film that inhibits hydrogen diffusion is specifically a film from which a small amount of hydrogen is released.

The amount of released hydrogen can be measured by thermal desorption spectroscopy (TDS) or the like, for example. The amount of hydrogen released from the insulator 324 that is converted into hydrogen atoms per area of the insulator 324 is less than or equal to 1×10¹⁶ atoms/cm², preferably less than or equal to 5×10¹⁵ atoms/cm², in TDS analysis in a film-surface temperature range of 50° C. to 500° C., for example.

Note that the dielectric constant of the insulator 326 is preferably lower than that of the insulator 324. For example, the relative dielectric constant of the insulator 326 is preferably lower than 4, further preferably lower than 3. In addition, the relative dielectric constant of the insulator 326 is, for example, preferably 0.7 times or less, further preferably 0.6 times or less the relative dielectric constant of the insulator 324. When a material with low dielectric constant is used for an interlayer film, parasitic capacitance generated between wirings can be reduced.

For example, a conductor having a function of electrically connecting the transistor 550 and the transistor 37 (e.g., a conductor 328, a conductor 330, and the like) is embedded in the insulator 320, the insulator 322, the insulator 324, and the insulator 326. Note that the conductor 328 and the conductor 330 each have a function of a plug or a wiring. A plurality of conductors functioning as plugs or wirings are collectively denoted by the same reference numeral in some cases. In this specification and the like, a wiring and a plug electrically connected to the wiring may be a single component. That is, part of a conductor functions as a wiring and part of a conductor functions as a plug in other cases.

As a material for each of the plugs and wirings (e.g., the conductor 328 and the conductor 330), a conductive material such as a metal material, an alloy material, a metal nitride material, or a metal oxide material can be used in a single-layer structure or a stacked-layer structure, for example. As the material for each of the plugs and the wirings, a high-melting point material that has both heat resistance and conductivity, such as tungsten or molybdenum, is preferably used, for example. Alternatively, as the material for each of the plugs and the wirings, a low-resistance conductive material such as aluminum or copper is preferably used. The use of a low-resistance conductive material for each of the plugs and the wirings can reduce wiring resistance.

A wiring layer may be provided over the insulator 326 and the conductor 330. For example, in FIG. 6, an insulator 350, an insulator 352, and an insulator 354 are sequentially stacked and provided. Furthermore, a conductor 356 is formed in the insulator 350, the insulator 352, and the insulator 354. The conductor 356 has a function of a plug or a wiring electrically connecting the transistor 550 to the transistor 37, for example. Note that the conductor 356 can be provided using a material similar to that for the conductor 328 or the conductor 330, for example.

Note that for example, the insulator 350 is preferably formed using an insulator having a barrier property against hydrogen, like the insulator 324. Furthermore, the conductor 356 preferably includes a conductor having a barrier property against hydrogen. The conductor having a barrier property against hydrogen is formed particularly in an opening portion of the insulator 350 having a barrier property against hydrogen. In such a structure, the transistor 550 and the transistor 37 can be separated by a barrier layer. Thus, the hydrogen diffusion from the transistor 550 into the transistor 37 can be inhibited.

For the conductor having a barrier property against hydrogen, tantalum nitride or the like is preferably used, for example. Tantalum nitride and tungsten, which has high conductivity, is preferably stacked. When the conductor 356 is a stack of tantalum nitride and tungsten, the conductor 356 can inhibit hydrogen diffusion from the transistor 550 while the conductivity as a wiring is ensured. In that case, a tantalum nitride layer of the conductor 356 having a barrier property against hydrogen is preferably in contact with the insulator 350 having a barrier property against hydrogen.

In the above, the wiring layer including the conductor 356 is described; however, the semiconductor device of one embodiment of the present invention is not limited thereto. A wiring layer similar to the wiring layer including the conductor 356 may have a single-layer structure or a stacked-layer structure of two or more layers.

### Transistor 37 and Capacitor 38

FIG. 8A to FIG. 8C are a plan view and cross-sectional views of the transistor 37 and the capacitor 38 included in the memory cell 32 that can be used in structures included in the element layer 30. FIG. 8A is a plan view of the memory cell 32. FIG. 8B and FIG. 8C are cross-sectional views of the memory cell 32. Here, FIG. 8B is a cross-sectional view of a portion indicated by the dashed-dotted line A1-A2 in FIG. 8A. FIG. 8C is a cross-sectional view of a portion indicated by the dashed-dotted line A3-A4 in FIG. 8A. Note that some components are omitted in the plan view of FIG. 8A for the sake of clarity of the drawing.

FIG. 8A to FIG. 8C illustrate an insulator 440, a conductor 410 over the insulator 440, the memory cell 32 over the conductor 410, an insulator 480 over the conductor 410, an insulator 280 over the insulator 480, and an insulator 283 over the memory cell 32. The insulator 440, the insulator 480, the insulator 280, and the insulator 283 each function as an interlayer film. The conductor 410 functions as a wiring.

The memory cell 32 includes the capacitor 38 over the conductor 410 and the transistor 37 over the capacitor 38.

As illustrated in FIG. 8A to FIG. 8C, the transistor 37 is provided to overlap with the capacitor 38. An opening portion 290 where part of the structures of the transistor 37 is provided includes a region overlapping with an opening portion 490 where part of the structures of the capacitor 38 is provided. In particular, since a conductor 420 has a function of one of a source electrode and a drain electrode of the transistor 37 and a function of one electrode of a pair of electrodes of the capacitor 38, the transistor 37 and the capacitor 38 partly share the structure. With such a structure, the transistor 37 and the capacitor 38 can be provided without a significant increase in the occupation area in the plan view. Thus, the area occupied by the memory cell 32 can be reduced, so that the memory cells 32 can be arranged densely and the memory capacity can be increased.

### Capacitor 38

The capacitor 38 includes a conductor 415 over the conductor 410, an insulator 430 over the conductor 415, and the conductor 420 over the insulator 430. The conductor 420 functions as one of a pair of electrodes (sometimes referred to as an upper electrode), the conductor 415 functions as the other of the pair of electrodes (sometimes referred to as a lower electrode), and the insulator 430 functions as a dielectric layer. That is, the capacitor 38 forms a MIM (Metal-Insulator-Metal) capacitor.

As illustrated in FIG. 8B and FIG. 8C, the opening portion 490 reaching the conductor 410 is provided in the insulator 480. At least part of the conductor 415 is placed in the opening portion 490. Note that the conductor 415 includes a region in contact with the top surface of the conductor 410 in the opening portion 490, a region in contact with a side surface of the insulator 480 in the opening portion 490, and a region in contact with at least part of the top surface of the insulator 480. The insulator 430 is placed so that at least part of the insulator 430 is positioned in the opening portion 490. The conductor 420 is placed so that at least part of the conductor 420 is positioned in the opening portion 490. Note that the conductor 420 is preferably provided to fill the opening portion 490 as illustrated in FIG. 8B and FIG. 8C.

The upper electrode and the lower electrode of the capacitor 38 face each other with the dielectric layer therebetween, along a side surface (sometimes referred to as a sidewall) of the opening portion 490 as well as the bottom surface (sometimes referred to as the bottom portion) thereof; thus, the capacitance per unit area can be larger. Thus, the deeper the opening portion 490 is, the larger the capacitance of the capacitor 38 can be. Increasing the capacitance per unit area of the capacitor 38 in this manner can stabilize the reading operation in a memory cell array. This also allows further miniaturization or high integration of the memory cell.

The sidewall of the opening portion 490 (sometimes referred to as a sidewall of the insulator 480 in the opening portion 490) is preferably perpendicular to the top surface of the conductor 410. In other words, the insulator 480 includes the opening portion 490 that is provided to extend in a direction perpendicular to the top surface of the conductor 410. At this time, the opening portion 490 has a cylindrical shape. With such a structure, the memory cell can be miniaturized and highly integrated.

Although this embodiment describes the example where the opening portion 490 has a circular shape in the plan view, one embodiment of the present invention is not limited thereto. For example, the opening portion 490 in the plan view may have an almost circular shape such as an elliptical shape, a polygonal shape such as a quadrangular shape, or a polygonal shape such as a quadrangular shape with rounded corners. In that case, the maximum width of the opening portion 490 is calculated as appropriate in accordance with the shape of the uppermost portion of the opening portion 490. For example, in the case where the opening portion 490 is square in the plan view, the maximum width of the opening portion 490 may be the length of a diagonal line of the uppermost portion of the opening portion 490.

Portions of the conductor 415, the insulator 430, and the conductor 420 that are placed in the opening portion 490 reflect the shape of the opening portion 490. Therefore, the conductor 415 is provided so as to cover the bottom portion and the sidewall of the opening portion 490, the insulator 430 is provided to cover the conductor 415, and the conductor 420 is provided so as to be embedded in a depressed portion reflecting the shape of the opening portion 490, of the insulator 430.

That is, part of the dielectric layer (corresponding to the insulator 430) of the capacitor 38 is provided along the sidewall of the opening portion 490. In other words, part of the dielectric layer is provided in a direction perpendicular to the top surface of the conductor 410. In other words, a surface where the upper electrode and the dielectric layer of the capacitor 38 are in contact with each other and a surface where the lower electrode and the dielectric layer of the capacitor 38 are in contact with each other each include a component in a direction perpendicular to the top surface of the conductor 410.

Although the opening portion 490 is provided so that the sidewall of the opening portion 490 is perpendicular to the top surface of the conductor 410 in FIG. 8B and FIG. 8C, one embodiment of the present invention is not limited thereto. The sidewall of the opening portion 490 may have a tapered shape, for example.

The conductor 415 and the insulator 430 are provided to be stacked along the sidewall of the opening portion 490 and the top surface of the conductor 410. The conductor 420 is provided over the insulator 430 to fill the opening portion 490. In this specification and the like, the capacitor 38 having such a structure is sometimes referred to as a trench-type capacitor, a trench capacitor, a deep-trench stacked capacitor, or the like.

The insulator 280 is provided over the capacitor 38. That is, the insulator 280 is placed over the conductor 415, the insulator 430, and the conductor 420. In other words, the conductor 420 is placed under the insulator 280.

The conductor 410 functions as the wiring CL illustrated in FIG. 6, for example. The conductor 420 functions as the node SN illustrated in FIG. 6, for example.

The conductor 410 is provided below the conductor 415. The conductor 415 includes a region in contact with the conductor 410.

The conductor 410 is provided over the insulator 440. The conductor 410 can be provided in a planar shape, for example. A single layer or stacked layers of conductors can be used as the conductor 410. A conductive material with high conductivity such as tungsten can be used for the conductor 410, for example. With the use of a conductive material with high conductivity, the conductivity of the conductor 410 can be improved.

A single-layer or stacked-layers of a conductive material that is less likely to be oxidized, a conductive material having a function of inhibiting diffusion of oxygen, or the like is preferably used for the conductor 415. For example, titanium nitride, indium tin oxide to which silicon is added, or the like may be used. A structure where titanium nitride is stacked over tungsten may be used, for example. A structure where tungsten is stacked over first titanium nitride and second titanium nitride is stacked over the tungsten may be used, for example. With such a structure, when an oxide insulator is used as the insulator 430, the conductor 415 can be inhibited from being oxidized by the insulator 430. Furthermore, in the case where an oxide insulator is used as the insulator 480, oxidation of the conductor 415 by the insulator 480 can be inhibited.

The insulator 430 is provided over the conductor 415. The insulator 430 is provided in contact with the top surface and a side surface of the conductor 415. That is, the insulator 430 preferably covers a side end portion of the conductor 415. This can prevent a short circuit between the conductor 415 and the conductor 420.

Note that as illustrated in FIG. 8B and FIG. 8C, the insulator 430 may be provided to extend and be in contact with the top surface of the insulator 480.

Alternatively, a side end portion of the insulator 430 and the side end portion of the conductor 415 may be aligned with each other. With such a structure, the insulator 430 and the conductor 415 can be formed using the same mask, so that the manufacturing process of the element layer 30 can be simplified.

For the insulator 430, a material with a high relative dielectric constant, what is called a high-k material, is preferably used. Using such a high-k material as the insulator 430 allows the insulator 430 to be thick enough to inhibit gate leakage current and the capacitor 38 to have a sufficiently high capacitance.

For the insulator 430, it is preferable to use stacked insulating layers formed using a high-k material, and it is preferable to use a stacked-layer structure including a high-k material and a material having higher dielectric strength than the high-k material. For example, as the insulator 430, an insulating film in which zirconium oxide, aluminum oxide, and zirconium oxide are stacked in this order can be used. Alternatively, an insulating film in which zirconium oxide, aluminum oxide, zirconium oxide, and aluminum oxide are stacked in this order can be used, for example. Alternatively, an insulating film in which hafnium zirconium oxide, aluminum oxide, hafnium zirconium oxide, and aluminum oxide are stacked in this order can be used, for example. The use of stacked insulators with relatively high dielectric strength, such as aluminum oxide, can increase the dielectric strength and inhibit electrostatic breakdown of the capacitor 38.

A material that can have ferroelectricity may be used for the insulator 430. Examples of the material that can have ferroelectricity include a metal oxide such as hafnium oxide, zirconium oxide, or HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, and strontium, for example) is added to hafnium oxide. Note that atomic ratio of a hafnium atom to the element J1 can be set as appropriate. For example, the atomic ratio of a hafnium atom to the element J1 is 1:1 or in the neighborhood thereof. Examples of the material that can have ferroelectricity also include a material in which an element J2 (the element J2 here is one or more selected from hafnium, silicon, aluminum, gadolinium, yttrium, lanthanum, and strontium, for example) is added to zirconium oxide. Note that the atomic ratio of a zirconium atom to the element J2 can be set as appropriate. For example, the atomic ratio of a zirconium atom to the element J2 can be 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used, for example.

Examples of the material that can have ferroelectricity also include a metal nitride containing an element M1, an element M2, and nitrogen. Here, the element M1 is one or more selected from aluminum, gallium, indium, and the like, for example. The element M2 is one or more selected from boron, scandium, yttrium, lanthanum, cerium, neodymium, europium, titanium, zirconium, hafnium, vanadium, niobium, tantalum, chromium, and the like, for example. Note that the atomic ratio of the element M1 to the element M2 can be set as appropriate. A metal nitride containing the element M1 and nitrogen has ferroelectricity in some cases even though the metal nitride does not contain the element M2. Examples of the material that can have ferroelectricity also include a material in which an element M3 is added to the above metal nitride. Here, the element M3 is one or more selected from magnesium, calcium, strontium, zinc, cadmium, and the like, for example. Note that the atomic ratio of the element MI to the element M2 to the element M3 can be set as appropriate.

Examples of the material that can have ferroelectricity also include a perovskite-type oxynitride such as SrTaO₂N or BaTaO₂N, GaFeO₃ with a k-alumina-type structure, and the like.

Although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulator 430 can have a stacked-layer structure of a plurality of materials selected from the above-listed materials. The above-listed materials and the like may change their crystal structures (characteristics) according to a variety of processes and the like as well as deposition conditions. Therefore, in this specification and the like, not only a material that exhibits ferroelectricity but also a material that can show ferroelectricity may be referred to as a ferroelectric.

A metal oxide containing one or both of hafnium and zirconium is preferable because the metal oxide can have ferroelectricity even when being processed into a thin film of several nanometers. Here, the thickness of the insulator 430 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). The thickness of the insulator 430 is preferably greater than or equal to 8 nm and less than or equal to 12 nm, for example. When the insulator 430 is a ferroelectric layer that can be thin, for example, the capacitor 38 can be combined with a semiconductor element such as a miniaturized transistor to form a semiconductor device. Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can show ferroelectricity even with a minute area. For example, a ferroelectric layer can have ferroelectricity even with an area (occupying area) less than or equal to 100 μm², less than or equal to 10 μm², less than or equal to 1 μm², or less than or equal to 0.1 μm² in a top view. Furthermore, even with an area less than or equal to 10000 nm² or less than or equal to 1000 nm², a ferroelectric layer can have ferroelectricity in some cases. With a small-area ferroelectric layer, the area occupied by the capacitor 38 can be reduced.

The ferroelectric is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory) or a ferroelectric memory, for example. For example, a ferroelectric memory has a structure which includes a transistor and a ferroelectric capacitor and in which one of a source and a drain of the transistor is electrically connected to one terminal of the ferroelectric capacitor. Thus, in the case of using a ferroelectric capacitor as the capacitor 38, the memory cell described in this embodiment functions as a ferroelectric memory.

Note that ferroelectricity is exhibited by displacement of oxygen or nitrogen of a crystal included in a ferroelectric layer due to electric field supplied from the outside. Ferroelectricity is presumably exhibited depending on a crystal structure of a crystal included in a ferroelectric layer. Thus, in order that the insulator 430 can exhibit ferroelectricity, the insulator 430 needs to include a crystal. It is particularly preferable that the insulator 430 include a crystal having an orthorhombic crystal structure to exhibit ferroelectricity. Note that a crystal structure of a crystal included in the insulator 430 may be one or more selected from a cubic crystal structure, a tetragonal crystal structure, an orthorhombic crystal structure, a monoclinic crystal structure, and a hexagonal crystal structure. Alternatively, the insulator 430 may have an amorphous structure. In that case, the insulator 430 may have a composite structure including an amorphous structure and a crystal structure.

The conductor 420 is provided in contact with part of the top surface of the insulator 430. A side end portion of the conductor 420 is preferably positioned inside the side end portion of the conductor 415 in both the X direction and the Y direction. Note that in the structure where the insulator 430 covers the side end portion of the conductor 415, the side end portion of the conductor 420 may be positioned outside the side end portion of the conductor 415.

A single layer or stacked layers of a conductive material can be used for the conductor 420. In addition, a conductive material that is less likely to be oxidized, a conductive material having a function of inhibiting diffusion of oxygen, or the like is preferably used for the conductor 420, for example. For example, titanium nitride, tantalum nitride, or the like can be used.

As illustrated in FIG. 6, in two adjacent capacitors 38, both of the conductors 420 may be integrally formed so that terminals on one side of the capacitors 38 are electrically connected to each other.

The insulator 480, which functions as an interlayer film, preferably has a low relative dielectric constant. When a material with a low relative dielectric constant is used for an interlayer film, parasitic capacitance generated between wirings can be reduced. As the insulator 480, a single layer or stacked layers of an insulator containing a material with a low relative dielectric constant can be used. Silicon oxide and silicon oxynitride are preferable because they are thermally stable. Here, the insulator 480 contains at least silicon and oxygen.

### Transistor 37

The transistor 37 includes the conductor 420, a conductor 240 over the insulator 280, an oxide semiconductor 230, an insulator 250 over the oxide semiconductor 230, and a conductor 260 over the insulator 250. The oxide semiconductor 230 functions as a semiconductor layer, the conductor 260 functions as a gate electrode, the insulator 250 functions as a gate insulator, the conductor 420 functions as one of a source electrode and a drain electrode, and the conductor 240 functions as the other of the source electrode and the drain electrode.

As illustrated in FIG. 8B and FIG. 8C, the opening portion 290 reaching the conductor 420 is provided in the insulator 280 and the conductor 240. At least part of the oxide semiconductor 230 is placed in the opening portion 290. The oxide semiconductor 230 includes a region in contact with the top surface of the conductor 420 in the opening portion 290, a region in contact with a side surface of the conductor 240 in the opening portion 290, and a region in contact with at least part of the top surface of the conductor 240. The insulator 250 is placed so that at least part of the insulator 250 is positioned in the opening portion 290. The conductor 260 is placed so that at least part of the conductor 260 is positioned in the opening portion 290. Note that the conductor 260 is preferably provided to fill the opening portion 290 as illustrated in FIG. 8B and FIG. 8C.

For example, a structure in which tantalum nitride is stacked over titanium nitride may be used for the conductor 420. In that case, titanium nitride is in contact with the insulator 430 and tantalum nitride is in contact with the oxide semiconductor 230. Such a structure can inhibit the excessive oxidation of the conductor 420 due to the oxide semiconductor 230. In the case of using an oxide insulator as the insulator 430, the excessive oxidation of the conductor 420 due to the insulator 430 can be inhibited. A structure in which tungsten is stacked over titanium nitride may be used for the conductor 420, for example.

The conductor 420 includes a region in contact with the oxide semiconductor 230 and thus is preferably formed using a conductive material containing oxygen. When a conductive material containing oxygen is used for the conductor 420, the conductor 420 can maintain its conductivity even when absorbing oxygen. For example, in the case where an insulator containing oxygen, such as zirconium oxide, is used as the insulator 430, the conductor 420 can maintain its conductivity. As the conductor 420, a single layer or stacked layers of indium tin oxide (also referred to as ITO), indium tin oxide to which silicon is added (also referred to as ITSO), indium zinc oxide (also referred to as IZO (registered trademark)), or the like can be used, for example.

The oxide semiconductor 230 includes the region in contact with the side surface of the conductor 240 in the opening portion 290 and a region in contact with part of the top surface of the conductor 240. When the oxide semiconductor 230 is in contact with not only the side surface but also the top surface of the conductor 240 in this manner, the area where the oxide semiconductor 230 and the conductor 240 are in contact with each other can be increased.

FIG. 8C illustrates a structure in which a side end portion of the oxide semiconductor 230 is positioned inside a side end portion of the conductor 240. Note that one embodiment of the present invention is not limited thereto. For example, in the Y direction, the side end portion of the oxide semiconductor 230 and the side end portion of the conductor 240 may be aligned with each other. The side end portion of the oxide semiconductor 230 may be positioned outside the side end portion of the conductor 240.

As illustrated in FIG. 8A to FIG. 8C, it is preferable that the conductor 260 be provided to extend in the Y direction and the conductor 240 be provided to extend in the X direction. With such a structure, the conductor 260 and the conductor 240 are provided to intersect with each other. Although the conductor 410 is provided in a plane shape in FIG. 8A, one embodiment of the present invention is not limited thereto. For example, the conductor 410 may be provided parallel to the conductor 260 or may be provided parallel to the conductor 240.

A sidewall of the opening portion 290 (sometimes referred to as a sidewall of the insulator 280 in the opening portion 290) is preferably perpendicular to the top surface of the conductor 410. In other words, the insulator 280 includes the opening portion 290 that is provided to extend in the direction perpendicular to the top surface of the conductor 410. At this time, the opening portion 290 has a cylindrical shape. With such a structure, a memory cell can be miniaturized or highly integrated.

Although this embodiment describes the example where the opening portion 290 has a circular shape in the plan view, one embodiment of the present invention is not limited thereto. For example, the opening portion 290 in the plan view may have an almost circular shape such as an elliptical shape, a polygonal shape such as a quadrangular shape, or a polygonal shape such as a quadrangular shape with rounded corners. In that case, the maximum width of the opening portion 290 is calculated as appropriate in accordance with the shape of the uppermost portion of the opening portion 290. For example, in the case where the opening portion 290 is square in the plan view, the maximum width of the opening portion 290 may be the length of a diagonal line of the uppermost portion of the opening portion 290.

Portions of the oxide semiconductor 230, the insulator 250, and the conductor 260 that are placed in the opening portion 290 reflect the shape of the opening portion 290. Therefore, the oxide semiconductor 230 is provided so as to cover the bottom portion and the sidewall of the opening portion 290, the insulator 250 is provided to cover the oxide semiconductor 230, and the conductor 260 is provided so as to be embedded in a depressed portion reflecting the shape of the opening portion 290, of the insulator 250.

That is, part of the semiconductor layer (corresponding to the oxide semiconductor 230) including a channel formation region of the transistor 37 is provided along the sidewall of the opening portion 290. In other words, part of the semiconductor layer is provided in a direction perpendicular to the top surface of the conductor 410. In other words, the channel length direction of the transistor 37 includes a component in a direction perpendicular to the top surface of the conductor 410. Thus, the transistor of one embodiment of the present invention can also be referred to as a VFET (Vertical Field-Effect Transistor), a vertical transistor, a vertical-channel transistor, or a vertical-channel-type transistor, for example.

Although the opening portion 290 is provided so that the sidewall of the opening portion 290 is perpendicular to the top surface of the conductor 410 in FIG. 8B and FIG. 8C, one embodiment of the present invention is not limited thereto. The sidewall of the opening portion 290 may have a tapered shape, for example.

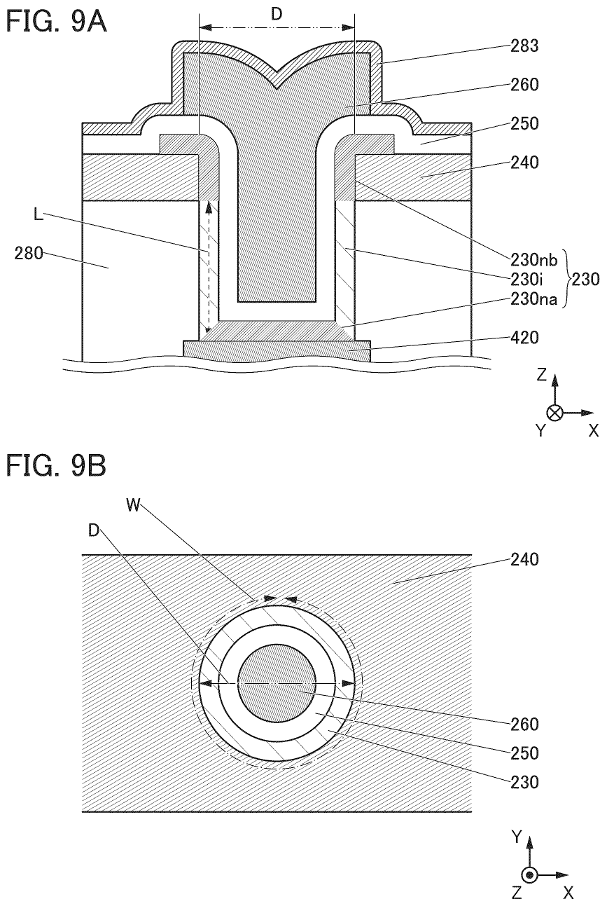

FIG. 9A illustrates an enlarged view of the oxide semiconductor 230 and its vicinity in FIG. 8B. FIG. 9B illustrates a cross-sectional view taken along the X-Y plane including the conductor 240.

As illustrated in FIG. 9A, the oxide semiconductor 230 includes a region 230i, and a region 230na and a region 230nb provided such that the region 230i is sandwiched therebetween.

The region 230na is a region in contact with the conductor 420 in the oxide semiconductor 230. At least part of the region 230na functions as one of a source region and a drain region of the transistor 37. The region 230nb is a region in contact with the conductor 240 in the oxide semiconductor 230. At least part of the region 230nb functions as the other of the source region and the drain region of the transistor 37. As illustrated in FIG. 9B, the conductor 240 is in contact with all the outer circumference of the oxide semiconductor 230. Thus, the other of the source region and the drain region of the transistor 37 can be formed along all the outer circumference of a portion formed in the same layer as the conductor 240 in the oxide semiconductor 230.

The region 230i is a region of the oxide semiconductor 230 between the region 230na and the region 230nb. At least part of the region 230i functions as the channel formation region of the transistor 37. That is, the channel formation region of the transistor 37 is positioned in a region of the oxide semiconductor 230 between the conductor 420 and the conductor 240. It can be said that the channel formation region of the transistor 37 is positioned in a region in contact with the insulator 280 or a region in the vicinity thereof in the oxide semiconductor 230.

The channel length of the transistor 37 is a distance between the source region and the drain region. In other words, the channel length of the transistor 37 is determined by the thickness of the insulator 280 over the conductor 420. In FIG. 9A, the channel length L of the transistor 37 is indicated by a dashed double-headed arrow. In the cross-sectional view, the channel length L is a distance between an end portion of a region where the oxide semiconductor 230 is in contact with the conductor 420 and an end portion of a region where the oxide semiconductor 230 is in contact with the conductor 240. That is, the channel length L corresponds to the length of a side surface of the insulator 280 on the opening portion 290 side in the cross-sectional view.

In a conventional transistor, the channel length is determined by the light exposure limit of photolithography. However in one embodiment of the present invention, the channel length can be determined by the thickness of the insulator 280. Thus, the transistor 37 can have an extremely minute structure where the channel length thereof is less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm). Accordingly, the transistor 37 can have higher on-state current and improved frequency characteristics. As a result, the reading speed and the writing speed of the memory cell 32 can be improved.

In addition, as described above, the channel formation region, the source region, and the drain region can be formed in the opening portion 290. Thus, the area occupied by the transistor 37 can be reduced as compared with a conventional transistor in which the channel formation region, the source region, and the drain region are provided separately on the X-Y plane. This allows high integration of the memory cell 32; therefore, the memory capacity per unit area can be increased.

Furthermore, in the X-Y plane including the channel formation region of the oxide semiconductor 230, as in FIG. 9B, the oxide semiconductor 230, the insulator 250, and the conductor 260 are provided concentrically. Therefore, a side surface of the conductor 260 provided at the center faces a side surface of the oxide semiconductor 230 with the insulator 250 therebetween. That is, in the plan view, the entire outer circumference of the oxide semiconductor 230 serves as the channel formation region. In this case, for example, the channel width of the transistor 37 is determined by the length of the outer circumference of the oxide semiconductor 230. In other words, the channel width of the transistor 37 is determined by the maximum width of the opening portion 290 (the maximum diameter in the case where the opening portion 290 is circular in the plan view). In FIG. 9A and FIG. 9B, the maximum width D of the opening portion 290 is denoted by a dashed double-dotted double-headed arrow. In FIG. 9B, the channel width W of the transistor 37 is denoted by a dashed-dotted double-headed arrow. By increasing the maximum width D of the opening portion 290, the channel width per unit area can be increased and the on-state current can be increased.

In the case where the opening portion 290 is formed by a photolithography method, the maximum width D of the opening portion 290 is determined by the light exposure limit of photolithography. In addition, the maximum width D of the opening portion 290 is determined by the thickness of each of the oxide semiconductor 230, the insulator 250, and the conductor 260 provided in the opening portion 290. The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the plan view, the maximum width D of the opening portion 290 corresponds to the diameter of the opening portion 290, and the channel width W can be calculated to be “D×π”.

In the memory cell 32 of one embodiment of the present invention, the channel length L of the transistor 37 is preferably smaller than at least the channel width W of the transistor 37. The channel length L of the transistor 37 in one embodiment of the present invention is greater than or equal to 0.1 times and less than or equal to 0.99 times, preferably greater than or equal to 0.5 times and less than or equal to 0.8 times the channel width W of the transistor 37. With such a structure, a transistor with favorable electrical characteristics and high reliability can be obtained.

In the case where the opening portion 290 is formed to be circular in the plan view, the oxide semiconductor 230, the insulator 250, and the conductor 260 are formed concentrically. This makes the distance between the conductor 260 and the oxide semiconductor 230 uniform or substantially uniform, so that a gate electric field can be uniformly or substantially uniformly applied to the oxide semiconductor 230.

It is preferable that a channel formation region of a transistor including an oxide semiconductor in a semiconductor layer contain less oxygen vacancies or have a lower impurity concentration (e.g., concentration of hydrogen, nitrogen, and a metal element) than a source region and a drain region. In some cases, hydrogen in the vicinity of an oxygen vacancy forms a defect that is an oxygen vacancy into which hydrogen enters (hereinafter sometimes referred to as VoH), which generates an electron serving as a carrier. Therefore, it is preferable that VoH be also decreased in the channel formation region. Thus, the channel formation region of the transistor is a high-resistance region having a low carrier concentration. Thus, the channel formation region of the transistor can be regarded as being i-type (intrinsic) or substantially i-type.

The source region and the drain region of the transistor using an oxide semiconductor in its semiconductor layer includes more oxygen vacancies, includes more VoH, or has a higher concentration of impurities (e.g., the concentration of hydrogen, nitrogen, and a metal element) than the channel formation region, and thus are low-resistance regions with high carrier concentrations. In other words, the source region and the drain region of the transistor are each an n-type region that has a higher carrier concentration and a lower resistance than the channel formation region.

The metal oxide used as the oxide semiconductor 230 preferably has a band gap of 2 eV or higher, further preferably 2.5 eV or higher. With the use of a metal oxide having a wide band gap as the oxide semiconductor 230, the off-state current of the transistor can be reduced. With use of the transistor with a low off-state current for a memory cell, stored contents can be retained for a long time. In other words, refresh operation is not required or the frequency of the refresh operation is extremely low, which leads to a sufficient reduction in power consumption of a memory cell array. The frequency of refresh operation in a general DRAM is approximately once per 60 msec, whereas the frequency of refresh operation in the semiconductor device of one embodiment of the present invention can be approximately once per 10 sec, which is greater than or equal to 10 times or greater than or equal to 100 times that of the general DRAM. In the semiconductor device of one embodiment of the present invention, the frequency of refresh operation can be once per period of more than or equal to 1 sec and less than or equal to 100 sec, preferably once per period of more than or equal to 5 sec and less than or equal to 50 sec.

As the oxide semiconductor 230, the metal oxide can be used as a single layer or stacked layers.

The metal oxide preferably contains at least one of indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin.

It is particularly preferable that an oxide containing indium (In), gallium (Ga), and zinc (Zn) (also referred to as “IGZO”) be used as the metal oxide. Alternatively, an oxide containing indium (In), aluminum (Al), and zinc (Zn) (also referred to as “IAZO”) may be used. Further alternatively, an oxide containing indium (In), aluminum (Al), gallium (Ga), and zinc (Zn) (also referred to as “IAGZO”) may be used. Further alternatively, an oxide containing indium (In), tin (Sn), and zinc (Zn) (also referred to as “ITZO (registered trademark)”) may be used. Further alternatively, an oxide containing indium (In), gallium (Ga), zinc (Zn), and tin (Sn) (also referred to as “IGZTO”) may be used.

When the metal oxide is an In—M—Zn oxide, the proportion of the number of In atoms is preferably higher than or equal to that of the number of M atoms in the In—M—Zn oxide. Examples of the atomic ratio of the metal elements in such an In—M—Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. The atomic ratio of In may be smaller than the atomic ratio of M in the In—M—Zn oxide. Examples of the atomic ratio of the metal elements in such an In—M—Zn oxide include In:M:Zn=1:3:2 or a composition in the neighborhood thereof and In:M:Zn=1:3:4 or a composition in the neighborhood thereof. Note that a composition in the neighborhood includes the range of ±30 % of an intended atomic ratio.

For example, when the atomic ratio is described as In:Ga:Zn=4:2:3 or a composition in the neighborhood thereof, the case is included where the content ratio of each element is as follows: Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where the content ratio of each element is as follows: Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where the content ratio of each element is as follows: Ga is greater than 0.1 and less than or equal to 2 and Zn is greater than 0.1 and less than or equal to 2 with In being 1.

In the case where the metal oxide is stacked to be used, for example, a three-layer stacked structure in which a first layer is a metal oxide in which the atomic ratio of metal elements is In:Ga:Zn=1:1:1, a second layer is a metal oxide in which the atomic ratio of metal elements is In:Zn=4:1, and a third layer is a metal oxide in which the atomic ratio of metal elements is In:Ga:Zn=1:1:1. Note that the band gaps of the first-layer and third-layer metal oxides are preferably larger than that of the second-layer metal oxide. With this structure, the main current path can be the second-layer metal oxide, so that what is called a buried channel structure can be obtained.

A sputtering method or an atomic layer deposition (ALD) method can be used for forming the metal oxide. Note that in the case where the metal oxide is formed by a sputtering method, the composition of the formed metal oxide may be different from the composition of a sputtering target. In particular, the content percentage of the zinc in the formed metal oxide may be reduced to approximately 50 % of that of the sputtering target.

The oxide semiconductor 230 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. As the oxide semiconductor 230, the CAAC-OS or the nc-OS is preferably used, and the CAAC-OS is particularly preferably used.

A CAAC-OS preferably includes a plurality of layered crystal regions and a c-axis is preferably aligned in a normal direction of a surface where the CAAC-OS is deposited. For example, the oxide semiconductor 230 preferably includes a layered crystal that is parallel to the sidewall of the opening portion 290, particularly the side surface of the insulator 280. With this structure, the layered crystals of the oxide semiconductor 230 are formed in parallel with the channel length direction of the transistor 37, so that the on-state current of the transistor can be increased.

Although FIG. 8B and FIG. 8C illustrate the oxide semiconductor 230 as a single-layer, one embodiment of the present invention is not limited thereto. The oxide semiconductor 230 may have a stacked-layer structure of a plurality of oxide layers with different chemical compositions. For example, a structure in which a plurality of kinds of metal oxides selected from the above-described metal oxides are stacked as appropriate may be used.

### Variation Example

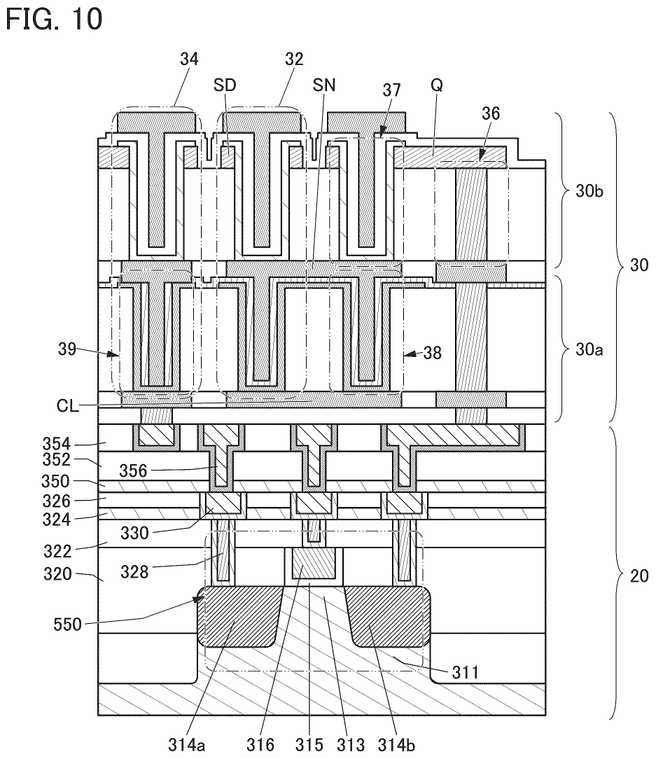

FIG. 10 is a variation example of the semiconductor device illustrated in FIG. 6. Here, differences from the semiconductor device illustrated in FIG. 6 are mainly described.

The semiconductor device illustrated in FIG. 10 includes a functional element 34 instead of the functional element 33. The functional element 34 includes a connection portion 39 and the transistor 37 provided over the connection portion 39.

The connection portion 39 is provided in the element layer 30a. The transistor 37 can be electrically connected to the transistor 550 provided in the element layer 20 through the connection portion 39.

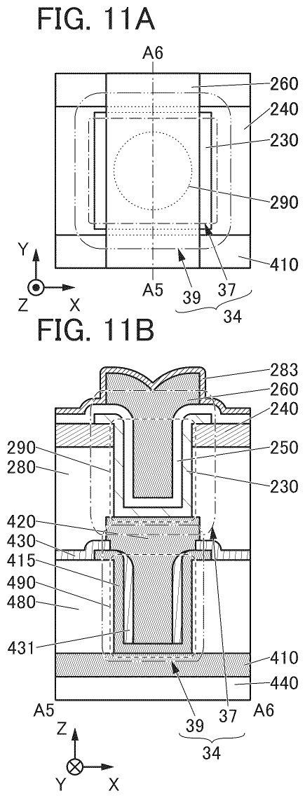

FIG. 11A and FIG. 11B are a plan view and a cross-sectional view, respectively, of the transistor 37 and the connection portion 39 included in the functional element 34. FIG. 11A is a plan view of the functional element 34. FIG. 11B is a cross-sectional view of the functional element 34. Here, FIG. 11B is a cross-sectional view of a portion indicated by the dashed-dotted line A5-A6 in FIG. 11A. Note that for clarity of the drawing, some components are not illustrated in the plan view in FIG. 11A.

The functional element 34 illustrated in FIG. 11A and FIG. 11B includes the transistor 37 and the connection portion 39. The functional element 34 has substantially the same structure as the memory cell 32 except that the structure of the insulator 430 is different, an insulator 431 is included, and the conductor 415 is in contact with the conductor 420.

In the functional element 34, an opening portion overlapping with the opening portion 490 is provided in the insulator 430. The opening portion of the insulator 430 is preferably provided to cover the opening portion 490. That is, in the plan view, the opening portion 490 is preferably positioned inside the opening portion of the insulator 430.

In addition, the insulator 431 is provided inside the opening portion 490 along a portion of the conductor 415 that is provided along an inner wall of the insulator 480. The insulator 431 is in contact with the conductor 415 and the conductor 420. The insulator 430 and the insulator 431 are formed by processing the same insulating film and contain the same element. The insulator 431 is formed in such a manner that part of the insulator 430 remains when a portion of the insulator 430 that is positioned on the bottom portion of the opening portion 490 is removed by anisotropic etching. The insulator 431 can also be referred to as a sidewall insulator.

Note that the insulator 431 is not formed in some cases depending on a method for processing an insulating film to be the insulator 430. In that case, the area where the conductor 420 and the conductor 415 are in contact with each other is large, which is preferable.

That is, the connection portion 39 has a structure in which part of the insulator 430 in the capacitor 38 is opened and the conductor 415 and the conductor 420 are in contact with each other through the opening.

Thus, electrical continuity between the conductor 420 and the conductor 415 is established; thus, electrical continuity between the conductor 420 and the conductor 410 is established through the conductor 415. That is, electrical continuity is established between the conductor 410 and one of a source electrode and a drain electrode of the transistor 37.

The semiconductor device and the arithmetic device of one embodiment of the present invention are not limited to those described in this embodiment. At least part of the structure examples, the operation examples, the drawings corresponding thereto, and the like described in this embodiment as an example can be combined with the other structure examples, the other operation examples, the other drawings, the other embodiments, and the like described in this specification and the like as appropriate.

### Embodiment 2

In this embodiment, a transistor including an oxide semiconductor in a channel formation region (OS transistor) will be described. In the description of the OS transistor, comparison with a transistor including silicon in a channel formation region (also referred to as a Si transistor) is also described simply.

### OS Transistor

An oxide semiconductor having a low carrier concentration is preferably used in an OS transistor. For example, the carrier concentration of an oxide semiconductor in the channel formation region is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration in an oxide semiconductor, the impurity concentration in the oxide semiconductor is reduced so that the density of defect states in the oxide semiconductor can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

In addition, a highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of the impurity include hydrogen and nitrogen. Note that impurities in an oxide semiconductor refer to, for example, elements other than the main components of an oxide semiconductor. For example, an element with a concentration lower than 0.1 atomic % can be regarded as an impurity.

When impurities or oxygen vacancies are in a channel formation region of the oxide semiconductor included in an OS transistor, electrical characteristics of the OS transistor may vary easily and the reliability thereof may worsen. In some cases, a defect that is an oxygen vacancy into which hydrogen enters (hereinafter sometimes referred to as VoH) is formed in the oxide semiconductor of the OS transistor, which generates an electron serving as a carrier. Formation of VoH in the channel formation region may increase the donor concentration in the channel formation region of the OS transistor. An increase in the donor concentration in the channel formation region of the OS transistor may lead to a variation in threshold voltage. Thus, the oxygen vacancies in the channel formation region of the oxide semiconductor allow the OS transistor to easily have normally-on characteristics (to cause the drain current to flow at a gate voltage of 0 V). Therefore, impurities, oxygen vacancies, and VoH are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current of the transistor (also referred to as Ioff) can be reduced.

In a Si transistor, a short-channel effect (SCE) appears as miniaturization of the transistor proceeds. This hinders miniaturization of a Si transistor. One factor in causing the short-channel effect is a narrow band gap of silicon. By contrast, the OS transistor includes an oxide semiconductor that is a semiconductor material having a wide band gap, and thus can suppress the short-channel effect. In other words, the OS transistor is a transistor in which the short-channel effect does not appear or hardly appears.

The short-channel effect refers to degradation of electrical characteristics that becomes obvious along with miniaturization of a transistor (a decrease in channel length). Specific examples of the short-channel effect include a decrease in threshold voltage, an increase in subthreshold swing value (sometimes referred to as an S value), and an increase in leakage current. Here, the S value means the amount of change in gate voltage in the subthreshold region when the drain voltage is constant and the drain current is changed by one order of magnitude.

The characteristic length is widely used as an indicator of resistance to the short-channel effect. The characteristic length is an indicator of curving of a potential in a channel formation region. The smaller the characteristic length is, the more sharply the potential rises; thus, a smaller characteristic length indicates higher resistance to the short-channel effect.

The OS transistor is an accumulation-type transistor and the Si transistor is an inversion-type transistor. Thus, the OS transistor has a shorter characteristic length between the source region and the channel formation region and a shorter characteristic length between the drain region and the channel formation region than the Si transistor has. Accordingly, the OS transistor has higher resistance to the short-channel effect than the Si transistor. That is, the OS transistor is more suitable than the Si transistor in the case where a short-channel transistor is to be formed.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region each become an n⁺-type region in the OS transistor.

The above-described structure enables the OS transistor to have excellent electrical characteristics even when the OS transistors are scaled down or highly integrated. For example, excellent electrical characteristics can be obtained even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Thus, the OS transistor can be used as a short-channel transistor than the Si transistor. Note that the gate length refers to the length of a gate electrode in a direction in which carriers move inside a channel formation region during operation of the transistor and to the width of the bottom surface of the gate electrode in a top view of the transistor.

Miniaturization of the OS transistor can improve the high frequency characteristics of the transistor. Specifically, the cutoff frequency of the transistor can be improved. When the gate length of the OS transistor is within the above-described range, the cutoff frequency of the transistor can be greater than or equal to 50 GHz, preferably greater than or equal to 100 GHx, further preferably greater than or equal to 150 GHz at room temperature, for example.

The above-described comparison of the OS transistor with the Si transistor demonstrates that the OS transistor has an effect superior to the Si transistor, such as a low off-state current and capability of short-channel transistor formation.

The structures, configurations, methods, and the like described in this embodiment can be used in combination as appropriate with the structures, configurations, methods, and the like described in the other embodiments and the like.

### Embodiment 3

This embodiment will describe an electronic component, an electronic device, a large computer, a device for space, and a data center (also referred to as a DC) that can use the semiconductor device described in the above embodiment. An electronic component, an electronic device, a large computer, a device for space, and a data center each using the semiconductor device of one embodiment of the present invention are effective in achieving high performance, e.g., reducing power consumption.

### Electronic Component

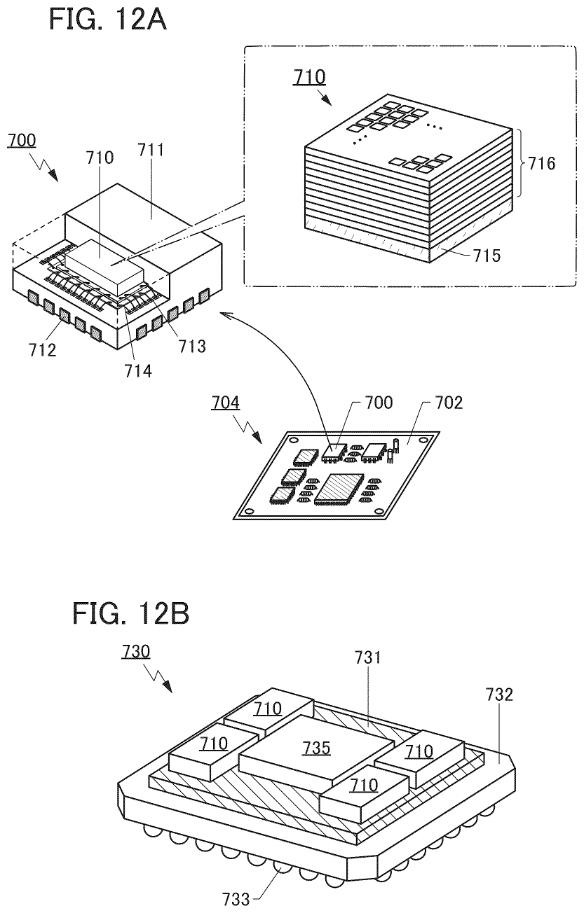

FIG. 12A is a perspective view of an electronic component 700 and a substrate (a circuit board 704) on which the electronic component 700 is mounted. The electronic component 700 illustrated in FIG. 12A includes a semiconductor device 710 in a mold 711. FIG. 12A omits illustrations of some parts to show the inside of the electronic component 700. The electronic component 700 includes a land 712 outside the mold 711. The land 712 is electrically connected to an electrode pad 713. The electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, whereby the circuit board 704 is completed.

The semiconductor device 710 includes a driver circuit layer 715 and a memory layer 716. Note that the memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu—Cu direct bonding, for example. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as a TSV is employed, for example; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. The monolithic stacked-layer structure of the plurality of memory cell arrays can improve the bandwidth of the memory and/or the access latency of the memory. Note that the bandwidth refers to the data transfer volume per unit time. The access latency refers to a period of time from data access to the start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

That is, an OS transistor has an excellent effect of achieving a wide memory bandwidth as compared with a Si transistor.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of semiconductor materials that can be used for the die include silicon, silicon carbide, and gallium nitride. A die obtained from a silicon substrate (also referred to as a silicon wafer) may be referred to as a silicon die, for example.

FIG. 12B is a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

In the electronic component 730, the semiconductor device 710 can be used as a memory device such as a high bandwidth memory (HBM), for example. The semiconductor device 735 can be used for an integrated circuit (e.g., an arithmetic device, a control device, or a signal processing device) such as a CPU (Central Processing Unit), a GPU (Graphics Processing Unit), or an FPGA (Field Programmable Gate Array), for example.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches through the plurality of wirings. The plurality of wirings have a single-layer structure or a multilayer structure. The interposer 731 has a function of electrically connecting an integrated circuit provided on the interposer 731 to an electrode provided on the package substrate 732. Accordingly, the interposer 731 is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer as the interposer 731, a TSV can also be used as the through electrode.

A silicon interposer is preferably used as the interposer 731. The silicon interposer can be formed at lower cost than an integrated circuit because it is not necessary to provide an active element. Furthermore, since wirings of a silicon interposer can be formed through a semiconductor process, formation of minute wirings, which is difficult for a resin interposer, is easy.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

For example, in a SiP, an MCM, or the like using a silicon interposer, a decrease in reliability due to a difference in the coefficient of expansion between an integrated circuit and the interposer is less likely to occur. Furthermore, the surface of a silicon interposer has high planarity, so that a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected with use of a silicon interposer, a TSV, and the like, a space for a width of the terminal pitch and the like is needed. Thus, in the case where the size of the electronic component 730 is to be reduced, the width of the terminal pitches causes a problem, which sometimes makes it difficult to provide a large number of wirings for obtaining a wide memory bandwidth. For this reason, the above-described monolithic stacked-layer structure using OS transistors is suitable. A composite structure combining memory cell arrays stacked using a TSV and monolithically stacked memory cell arrays may be employed.

The substrate on which the electronic component 730 is mounted may be provided with a heat sink (a radiator plate) overlapping with the electronic component 730. In the case of providing a heat sink, the heights of integrated circuits provided on the interposer 731 are preferably equal to each other. For example, in the electronic component 730, the heights of the semiconductor device 710 and the semiconductor device 735 are preferably equal to each other.

An electrode 733 may be provided on the bottom portion of the package substrate 732 to mount the electronic component 730 on another substrate. FIG. 12B illustrates an example in which the electrode 733 is formed of a solder ball. Solder balls are provided in a matrix on the bottom portion of the package substrate 732, whereby BGA (Ball Grid Array) mounting can be achieved in the electronic component 730. Note that the electrode 733 may be formed of a conductive pin. When conductive pins are provided in a matrix on the bottom portion of the package substrate 732, PGA (Pin Grid Array) mounting can be achieved in the electronic component 730.

The electronic component 730 can be mounted on another substrate by various mounting methods not limited to BGA or PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

### Electronic Device

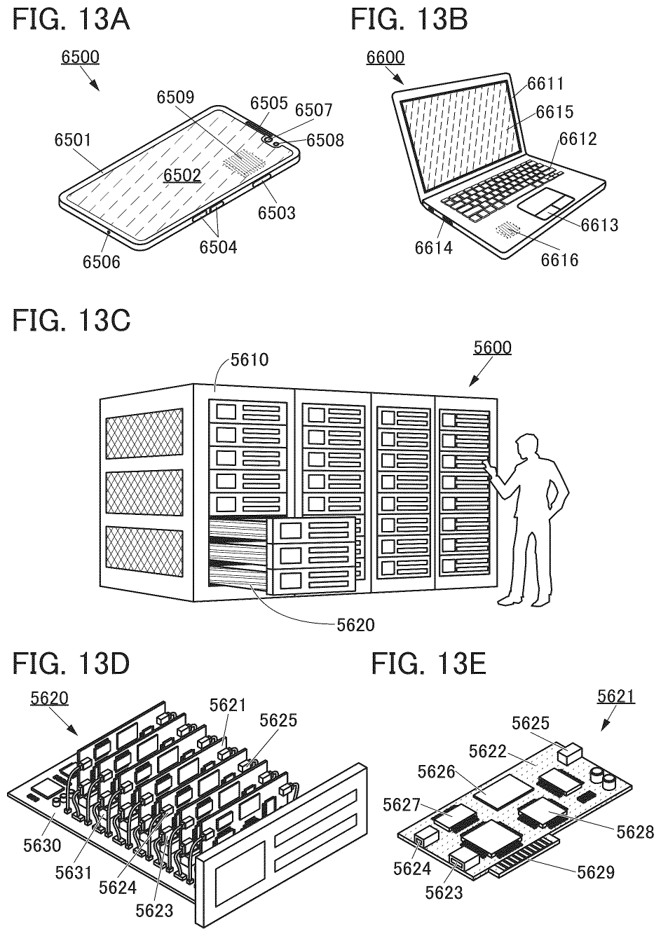

FIG. 13A is a perspective view of an electronic device 6500. The electronic device 6500 illustrated in FIG. 13A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, and a control device 6509, for example. Note that the control device 6509 includes one or more selected from a CPU, a GPU, and a memory device, for example. The semiconductor device of one embodiment of the present invention can be used for the display portion 6502 or the control device 6509, for example. The semiconductor device of one embodiment of the present invention is preferably used for the control device 6509, in which case power consumption can be reduced.

FIG. 13B is a perspective view of an electronic device 6600. The electronic device 6600 illustrated in FIG. 13B is an information terminal that can be used as a notebook personal computer. The electronic device 6600 includes a housing 6611, a keyboard 6612, a pointing device 6613, an external connection port 6614, a display portion 6615, and a control device 6616, for example. Note that the control device 6616 includes one or more selected from a CPU, a GPU, and a memory device, for example. The semiconductor device of one embodiment of the present invention can be employed for the control device 6509 or the control device 6616, for example. The semiconductor device of one embodiment of the present invention is preferably used as the control device 6616, in which case power consumption can be reduced.

### Large Computer

FIG. 13C is a perspective view of a large computer 5600. In the large computer 5600 illustrated in FIG. 13C, a plurality of rack mount computers 5620 are stored in a rack 5610. Note that the large computer 5600 may be referred to as a supercomputer.

FIG. 13D is a perspective view illustrating a structure example of the computer 5620. In FIG. 13D, the computer 5620 includes a motherboard 5630. The motherboard 5630 includes a plurality of slots 5631 and a plurality of connection terminals (not illustrated). A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 13E is an example of a processing board provided with a CPU, a GPU, and a memory device, for example. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 13E illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe (Peripheral Component Interconnect Express).

Each of the connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), SCSI (Small Computer System Interface), and the like. In the case where video signals are output from the connection terminal 5623, the connection terminal 5624, and the connection terminal 5625, an example of the standard therefor is HDMI (registered trademark) (High-Definition Multimedia Interface).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the above-described electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the above-described electronic component 700 can be used, for example.

The large computer 5600 can also function as a parallel computer. When the large computer 5600 is used as a parallel computer, large-scale computation necessary for artificial intelligence learning and inference can be performed, for example.

### Device for Space

The semiconductor device of one embodiment of the present invention can be used as a device for space such as devices processing and storing information, for example.

The semiconductor device of one embodiment of the present invention can include an OS transistor. A change in electrical characteristics of the OS transistor due to radiation irradiation is small. That is, the OS transistor is highly resistant to radiation, and thus can be suitably used in an environment where radiation can enter. For example, the OS transistor is suitably used in outer space.

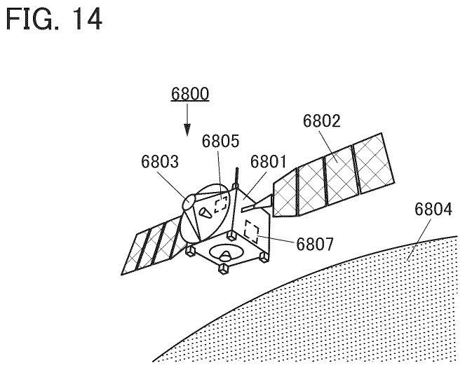

FIG. 14 illustrates an artificial satellite 6800 as an example of a device for space. The artificial satellite 6800 includes a body 6801, a solar panel 6802, an antenna 6803, a secondary battery 6805, and a control device 6807. In FIG. 14, a planet 6804 in outer space is illustrated as an example. Note that outer space refers to, for example, space at an altitude greater than or equal to 100 km, and outer space described in this specification and the like may include thermosphere, mesosphere, and stratosphere.

Although not illustrated in FIG. 14, the secondary battery 6805 may be provided with a battery management system (also referred to as a BMS) or a battery control circuit. The battery management system or the battery control circuit preferably uses the OS transistor, in which case power consumption is low and high reliability is achieved even in outer space.

The amount of radiation in outer space is 100 or more times that on the ground. Note that examples of radiation include electromagnetic waves (electromagnetic radiation) typified by X-rays or gamma rays and particle radiation typified by alpha rays, beta rays, neutron beams, proton beams, heavy-ion beams, and meson beams.

When the solar panel 6802 is irradiated with sunlight, power required for the operation of the artificial satellite 6800 is generated. However, for example, in the situation where the solar panel 6802 is not irradiated with sunlight or the amount of sunlight with which the solar panel 6802 is irradiated is small, the amount of power generated by the solar panel 6802 is small. Accordingly, a sufficient amount of power required for the operation of the artificial satellite 6800 might not be generated. In order to operate the artificial satellite 6800 even with a small amount of power generated by the solar panel 6802, the artificial satellite 6800 is preferably provided with the secondary battery 6805. Note that the solar panel 6802 is referred to as a solar cell module in some cases.

The artificial satellite 6800 can generate a signal. The signal is transmitted through the antenna 6803. The signal can be received by a ground-based receiver or another artificial satellite, for example. When the receiver receives the signal transmitted by the artificial satellite 6800, the position of the receiver can be measured. Thus, the artificial satellite 6800 can constitute a satellite positioning system.

The control device 6807 has a function of controlling the artificial satellite 6800. The control device 6807 is formed with one or more selected from a CPU, a GPU, and a memory device, for example. Note that the semiconductor device including the OS transistor, which is one embodiment of the present invention, is suitably used for the control device 6807. A change in electrical characteristics due to radiation irradiation is smaller in an OS transistor than in a Si transistor. Accordingly, the OS transistor has high reliability even in an environment where radiation can enter and thus is preferable.

That is, an OS transistor has an excellent effect of being highly resistant to radiation as compared with a Si transistor.

The artificial satellite 6800 can include a sensor. For example, with a structure including a visible light sensor, the artificial satellite 6800 can have a function of sensing sunlight reflected by a ground-based object. With a structure including a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be used for a device for space such as a spacecraft, a space capsule, or a space probe, for example.

### Data Center

The semiconductor device of one embodiment of the present invention can be used for a storage system in a data center, for example. Long-term management of data, such as guarantee of data immutability, is required for the data center, for example. In the case where data is managed for a long term, installation of storages and servers for storing an enormous amount of data, ensuring stable electric power for data retention, ensuring cooling equipment for data retention, or the like is necessary, for example. Therefore, for example, an increase in the scale of data center facility is necessary.

With use of the semiconductor device of one embodiment of the present invention for a storage system used in a data center, power used for retaining data can be reduced and the semiconductor device for retaining data can be downsized. Accordingly, downsizing of the storage system, downsizing of the power supply for retaining data, downscaling of the cooling equipment, and the like can be achieved, for example. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a peripheral module. Furthermore, the use of the semiconductor device of one embodiment of the present invention enables a data center that operates stably even in a high-temperature environment. Thus, the reliability of the data center can be increased.

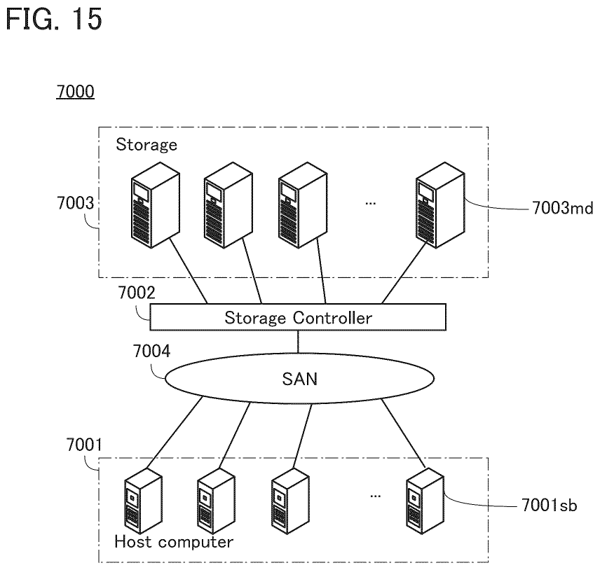

FIG. 15 illustrates a storage system that can be used in a data center. A storage system 7000 illustrated in FIG. 15 includes a plurality of servers 7001sb as a host 7001 (indicated as “Host Computer” in the diagram). The storage system 7000 includes a plurality of memory devices 7003md as a storage 7003 (indicated as “Storage” in the diagram). Furthermore, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for writing or reading data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for writing or reading data.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the above-described cache memory to retain a potential based on data can reduce the refresh frequency of the above-described cache memory, so that power consumption of the above-described cache memory can be reduced. Furthermore, with a structure in which memory cell arrays are stacked, the cache memory can be downsized.

Note that the use of the semiconductor device of one embodiment of the present invention for one or more selected from an electronic component, an electronic device, a large computer, a device for space, and a data center, so that power consumption can be reduced. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. Furthermore, the semiconductor device of one embodiment of the present invention has low power consumption and thus is effective as a global warming countermeasure.

The structures, configurations, methods, and the like described in this embodiment can be used in combination as appropriate with the structures, configurations, methods, and the like described in the other embodiments and the like.

### Supplementary Notes on Description in this Specification and the like

The following are notes on the description of the foregoing embodiments and the structures in the embodiments.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, e.g., a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

Here, the expression “X and Y are electrically connected” means the case where electric signals can be transmitted and received between X and Y when an object having any electric action is present between X and Y. For example, in the case where X and Y are electrically connected, one or more elements that allow electrical connection between X and Y (e.g., a switch, a transistor, a capacitor, an inductor, a resistor, a diode, a display device, a light-emitting device, or a load) can be connected between X and Y.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit (e.g., a step-up circuit or a step-down circuit) or a level shifter circuit for changing the potential level of a signal); a voltage source; a current source; a switch circuit; an amplifier circuit (e.g., a circuit that can increase signal amplitude, the current amount, or the like, an operational amplifier, a differential amplifier circuit, a source follower circuit, or a buffer circuit); a signal generation circuit; a memory circuit; or a control circuit) can be connected between X and Y. For instance, even if another circuit is interposed between X and Y, X and Y are regarded as being functionally connected when a signal output from X is transmitted to Y.

Note that an explicit description that X and Y are electrically connected includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (sometimes called one of a first terminal and a second terminal in this specification and the like) of a transistor, and a drain (sometimes called the other of the first terminal and the second terminal in this specification and the like) of the transistor are electrically connected to each other, and X, the source of the transistor, the drain of the transistor, and Y are electrically connected to each other in this order”. Alternatively, it can be expressed as “a source of a transistor is electrically connected to X; a drain of the transistor is electrically connected to Y; and X, the source of the transistor, the drain of the transistor, and Y are electrically connected to each other in this order”. Alternatively, it can be expressed as “X is electrically connected to Y through a source and a drain of a transistor, and X, the source of the transistor, the drain of the transistor, and Y are provided in this connection order”. When the connection order in a circuit structure is defined by an expression like the above examples, a source and a drain of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: the wiring and the electrode. Thus, electrical connection in this specification and the like includes, in its category, such a case where one conductive film has functions of a plurality of components.

In this specification and the like, as a “resistor”, a circuit element, a wiring, or the like having a resistance value higher than 0 Ω can be used, for example. Accordingly, in this specification and the like, examples of the “resistor” include a wiring having a resistance value, a transistor in which current flows between its source and drain, a diode, and a coil. Thus, the term “resistor” can be replaced with the term “resistance”, “load”, “region having a resistance value”, or the like. Conversely, the terms “resistance”, “load”, and “region having a resistance value” can be replaced with the term “resistor”, or the like. The resistance value can be, for example, preferably higher than or equal to 1 mΩ and lower than or equal to 10 Ω, further preferably higher than or equal to 5 mΩ and lower than or equal to 5 Ω, still further preferably higher than or equal to 10 mΩ and lower than or equal to 1 Ω. As another example, the resistance value may be higher than or equal to 1 Ω and lower than or equal to 1×10⁹ Ω.

In the case where a wiring is used as a resistor, the resistance value of the resistor is sometimes determined depending on the length of the wiring. Alternatively, a conductor with resistivity different from that of a conductor used as a wiring is sometimes used as a resistor. Alternatively, in the case where a semiconductor is used as a resistor, the resistance value of the resistor is sometimes determined by doping the semiconductor with an impurity.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. Thus, in this specification and the like, a “capacitor” is not limited to only a circuit element that has a pair of electrodes and a dielectric between the electrodes. A “capacitor” includes, for example, parasitic capacitance generated between wirings, gate capacitance generated between a gate and one of a source and a drain of a transistor, and the like. The term “capacitor”, “parasitic capacitance”, “gate capacitance”, or the like can be replaced with the term “capacitance” and the like, for example. Conversely, the term “capacitance” can be replaced with the term “capacitor”, “parasitic capacitance”, “gate capacitance”, or the like, for example. The term “a pair of electrodes” of a “capacitor” can be replaced with “a pair of conductors”, “a pair of conductive regions”, “a pair of regions”, or the like, for example. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

A transistor in this specification and the like has three terminals called a gate (also referred to as a gate terminal, a gate region, or a gate electrode), a source (also referred to as a source terminal, a source region, or a source electrode), and a drain (also referred to as a drain terminal, a drain region, or a drain electrode). The transistor has a region where a channel is formed (also referred to as a channel formation region) between the drain and the source. In the transistor, current can flow through the channel formation region between the source and the drain. The channel formation region refers to a region through which current mainly flows. The gate is a control terminal for controlling the amount of current flowing through the channel formation region between the source and the drain. Two terminals functioning as the source and the drain are input/output terminals of the transistor.

Note that one of the two input/output terminals serves as the source and the other serves as the drain depending on the conductivity type (n-channel type or p-channel type) of the transistor and the levels of potentials supplied to the three terminals of the transistor. In some cases, the function of the source and the function of the drain are replaced with each other when the direction of current flow is changed in circuit operation, for example. Thus, the terms “source” and “drain” can be replaced with each other in this specification and the like. Furthermore, in this specification and the like, expressions “one of a source and a drain” (or a first electrode or a first terminal) and “the other of the source and the drain” (or a second electrode or a second terminal) are used in the description of the connection relationship of a transistor.

Depending on the structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, each of the gates may be referred to as a first gate, a second gate, or a third gate, for example, in this specification and the like.

In this specification and the like, a transistor having a multi-gate structure having two or more gate electrodes can be used as the transistor. In the transistor having the multi-gate structure, channel formation regions are connected in series; accordingly, a plurality of transistors are connected in series. Thus, in the transistor having the multi-gate structure, the amount of off-state current can be reduced, and the withstand voltage of the transistor can be increased (the reliability can be improved). Alternatively, in the transistor having the multi-gate structure, a drain-source current does not change very much even if a drain-source voltage changes at the time of operation in a saturation region, so that a flat slope of voltage-current characteristics can be obtained. The transistor having the flat slope of the voltage-current characteristics enables an ideal current source circuit or an active load having an extremely high resistance value. As a result, the transistor having the flat slope of the voltage-current characteristics enables, for example, a differential circuit, a current mirror circuit, or the like having high characteristics.

In this specification and the like, the case where a single circuit element is illustrated in a circuit diagram may indicate a case where the circuit element includes a plurality of circuit elements. For example, the case where a single resistor is illustrated in a circuit diagram may indicate a case where two or more resistors are electrically connected to each other in series. As another example, the case where a single capacitor is illustrated in a circuit diagram may indicate a case where two or more capacitors are electrically connected to each other in parallel. As another example, the case where a single transistor is illustrated in a circuit diagram may indicate a case where two or more transistors are electrically connected to each other in series and their gates are electrically connected to each other. Similarly, as another example, the case where a single switch is illustrated in a circuit diagram may indicate a case where the switch includes two or more transistors which are electrically connected to each other in series or in parallel and whose gates are electrically connected to each other.

In this specification and the like, a “node” can be referred to as a “terminal”, a “wiring”, an “electrode”, a “conductive layer”, a “conductor”, an “impurity region”, or the like depending on the circuit structure, the device structure, or the like, for example. Furthermore, a “terminal”, a “wiring”, or the like can be referred to as a “node”, for example.

In this specification and the like, “voltage” and “potential” can be replaced with each other as appropriate. The term “voltage” refers to a potential difference from a reference potential. When the reference potential is a ground potential, for example, “voltage” can be replaced with “potential”. Note that the ground potential does not necessarily mean 0 V. Moreover, potentials are relative values. That is, a potential supplied to a wiring, a potential applied to a circuit and the like, or a potential output from a circuit and the like, are changed with a change of the reference potential.

In this specification and the like, the terms “high-level potential” (also referred to as “H potential” or “H”) and “low-level potential” (also referred to as “L potential” or “L”) do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

In this specification and the like, “current” means a charge transfer (electrical conduction). For example, the description “electrical conduction of positively charged particles occurs” can be rephrased as “electrical conduction of negatively charged particles occurs in the opposite direction”. Thus, unless otherwise specified, “current” in this specification and the like refers to a charge transfer (electrical conduction) accompanied by carrier movement. Examples of a carrier here include an electron, a hole, an anion, a cation, and a complex ion. The type of carrier differs depending on current-flowing systems (e.g., a semiconductor, a metal, an electrolyte solution, or a vacuum). For example, the “direction of current” in a wiring or the like refers to the direction in which a positive carrier moves, and the amount of current is expressed as a positive value. In other words, the direction in which a negative carrier moves is opposite to the direction of current, and the amount of current is expressed as a negative value. Thus, in the case where the polarity of current (or the direction of current) is not specified in this specification and the like, the description “current flows from element A to element B” can be rephrased as “current flows from element B to element A” and the like, for example. The description “current is input to element A” and the like can be rephrased as “current is output from element A” and the like, for example.

Ordinal numbers such as “first”, “second”, and “third” in this specification and the like are used to avoid confusion among components. Thus, the ordinal numbers do not limit the number of components. In addition, the ordinal numbers do not limit the order of components. For example, a “first” component in one embodiment in this specification and the like can be referred to as a “second” component in other embodiments, the scope of claims, or the like. Furthermore, for example, a “first” component in one embodiment in this specification and the like can be omitted in other embodiments, the scope of claims, or the like.

In this specification and the like, for example, terms for describing arrangement, such as “over”, “under”, “above”, and “below” are sometimes used for convenience to describe the positional relationship between components with reference to drawings. The positional relationship between components is changed as appropriate in accordance with a direction in which each component is described. Thus, the terms for describing arrangement in this specification and the like are not limited to those and can be replaced with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°. Moreover, the expression “an insulator positioned over (on) a top surface of a conductor” can be replaced with the expression “an insulator positioned on a left surface (or a right surface) of a conductor” when the direction of a drawing illustrating these components is rotated by 90°.

The term “over” or “under” does not necessarily mean that a component is placed directly over or directly under and directly in contact with another component. For example, the expression “electrode B over insulating layer A” does not necessarily mean that the electrode B is formed over and in direct contact with the insulating layer A, and does not exclude the case where another component is provided between the insulating layer A and the electrode B.

In this specification and the like, components arranged in a matrix and their positional relationship are sometimes described using a term such as “row” or “column”, for example. The positional relationship between components is changed as appropriate in accordance with a direction in which each component is described. Thus, for example, the terms such as “row” and “column” are not limited to those described in this specification and the like and can be replaced with another term as appropriate depending on the situation. For example, the term “row direction” can be replaced with the term “column direction” when the direction of the diagram is rotated by 90°.

Furthermore, the term “overlap”, for example, in this specification and the like does not limit a state such as the stacking order of components. For example, the expression “electrode B overlapping with insulating layer A” does not necessarily mean the state where the electrode B is formed over the insulating layer A. The expression “electrode B overlapping with insulating layer A”, for example, does not exclude the state where the electrode B is formed under the insulating layer A and the state where the electrode B is formed on the right side (or the left side) of the insulating layer A.

The term “adjacent” or “proximity” in this specification and the like does not necessarily mean that a component is directly in contact with another component. For example, the expression “electrode B adjacent to insulating layer A” does not necessarily mean that the electrode B is formed in direct contact with the insulating layer A and does not exclude the case where another component is placed between the insulating layer A and the electrode B.

In this specification and the like, the term “film”, “layer”, or the like can be, for example, interchanged with each other depending on the situation, in some cases. For example, the term “conductive layer” can be changed into the term “conductive film” in some cases. For another example, the term “insulating film” can be changed into the term “insulating layer” in some cases. Alternatively, for example, the term “film”, “layer”, or the like is not used and can be interchanged with another term depending on the situation, in some cases. For example, the term “conductive layer” or “conductive film” can be changed into the term “conductor” in some cases. Furthermore, the term “conductor” can be changed into the term “conductive layer” or “conductive film” in some cases. For example, the term “insulating layer” or “insulating film” can be changed into the term “insulator” in some cases. Furthermore, the term “insulator” can be changed into the term “insulating layer” or “insulating film” in some cases.

In addition, in this specification and the like, for example, the term such as “electrode”, “wiring”, or “terminal” does not limit the function of a component. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Thus, for example, an “electrode” can be part of a “wiring” or a “terminal”. Furthermore, a “terminal” can be part of a “wiring” or an “electrode”. Moreover, the term “electrode”, “wiring”, “terminal”, or the like is sometimes replaced with the term “region”, for example.

In addition, in this specification and the like, for example, the terms such as “wiring”, “signal line”, and “power supply line” can be interchanged with each other depending on the situation, in some cases. For example, the term “wiring” can be changed into the term “signal line” in some cases. For another example, the term “wiring” can be changed into the term “power supply line” or the like in some cases. Conversely, for example, the term “signal line”, “power supply line”, or the like can be changed into the term “wiring” in some cases. Furthermore, for example, the term “power supply line” or the like can be changed into the term “signal line” or the like in some cases. Conversely, for example, the term “signal line” or the like can be changed into the term “power supply line” or the like in some cases. Moreover, the term “potential” that is applied to a wiring can be changed into the term “signal” or the like depending on the situation, for example. Conversely, for example, the term “signal” or the like can be changed into the term “potential” in some cases.

In this specification and the like, a “switch” includes a plurality of terminals and has a function of switching (selecting) electrical continuity and discontinuity between the terminals. For example, in the case where a switch includes two terminals and electrical continuity is established between the two terminals, the switch is in a “conduction state” or an “on state”. In the case where electrical continuity is not established between the two terminals, the switch is in a “non-conduction state” or an “off state”. Note that switching to one of a conduction state and a non-conduction state or maintaining one of a conduction state and a non-conduction state is sometimes referred to as “controlling a conduction state”.

That is, a switch has a function of controlling whether current flows therethrough or not. Alternatively, a switch has a function of selecting and changing a current path. For example, an electrical switch or a mechanical switch can be used as the switch. That is, a switch can be any element capable of controlling current, and is not limited to a particular element.

Note that as a kind of a switch, there is a switch which is normally in a non-conduction state and brought into a conduction state by controlling a conduction state; such a switch is referred to as an “A contact” in some cases. Furthermore, as another kind of a switch, there is a switch which is normally in a conduction state and brought into a non-conduction state by controlling a conduction state; such a switch is referred to as a “B contact”in some cases.

Examples of an electrical switch include a transistor (e.g., a bipolar transistor or a MOS transistor), a diode (e.g., a PN diode, a PIN diode, a Schottky diode, a MIM (Metal Insulator Metal) diode, a MIS (Metal Insulator Semiconductor) diode, or a diode-connected transistor), and a logic circuit in which such elements are combined. Note that in the case where a transistor operates just as a switch, there is no particular limitation on the polarity (conductivity type) of the transistor.

An example of a mechanical switch is a switch using a MEMS (micro electro mechanical systems) technology. Such a switch includes an electrode that can be moved mechanically, and selects a conduction or non-conduction state with the movement of the electrode.

In this specification and the like, the “channel length” of the transistor sometimes refers to, for example, the distance between a source and a drain in a region where a semiconductor (or a portion where current flows in a semiconductor when a transistor is in an on state) and a gate overlap with each other or the distance between the source and the drain of a region where a channel is formed.

In this specification and the like, the “channel width” of the transistor sometimes refers to, for example, the length of a portion where a source and a drain face each other in a region where a semiconductor (or a portion where current flows in a semiconductor when a transistor is an on state) and a gate overlap with each other or the length of a portion where a source and a drain face each other in a region where a channel is formed.

In this specification and the like, for example, the terms such as “substrate”, “wafer”, and “die” do not functionally limit these components. For example, the terms such as “substrate,” “wafer,” and “die” can be interchanged with each other depending on the situation in some cases.

In this specification and the like, the term “parallel” does not necessarily mean a state being exactly parallel. Hence, for example, the term “parallel” can be replaced with the term “approximately parallel,” “substantially parallel,” “practically parallel,” or the like as appropriate. In addition, the term “parallel”, “approximately parallel,” “substantially parallel,” or “practically parallel,” may be applied to the case where the angle between two straight lines or planes is greater than or equal to −5° and less than or equal to 5°. Alternatively, these terms may be applied to the case where the angle between two straight lines or planes is greater than or equal to −10° and less than or equal to 10°. Alternatively, these terms may be applied to the case where the angle between two straight lines or planes is greater than or equal to −30° and less than or equal to 30°. Accordingly, the term “parallel” sometimes means a state being “parallel or substantially parallel,” for example. Moreover, the term “perpendicular” does not necessarily mean that a state being exactly perpendicular. Hence, for example, the term “perpendicular” can be replaced with the term “approximately perpendicular,” “substantially perpendicular,” “practically perpendicular,” or the like as appropriate. The term “perpendicular”, “approximately perpendicular,” “substantially perpendicular,” or “practically perpendicular,” may be applied to the case where the angle between two straight lines or planes is greater than or equal to 85° and less than or equal to 95°. Alternatively, these terms may be applied to the case where the angle between two straight lines or planes is greater than or equal to 80° and less than or equal to 100°. Alternatively, these terms may be applied to the case where the angle between two straight lines or planes is greater than or equal to 60° and less than or equal to 120°. Accordingly, the term “perpendicular” sometimes means a state being “perpendicular or substantially perpendicular,” for example.

Note that in this specification and the like, the expression “level or substantially level” indicates having the same level from a reference surface (e.g., a flat surface such as a substrate surface) in a cross-sectional view. For example, in a manufacturing process of the semiconductor device, planarization treatment is performed, whereby the surface(s) of a single layer or a plurality of layers are exposed in some cases. In this case, the surfaces on which the planarization treatment has been performed are at the same level as a reference surface. Note that a plurality of layers having the surfaces on which the planarization treatment has been performed are not level with each other in the strict sense in some cases, depending on a treatment apparatus, a treatment method, or a material of the treated surfaces on which the planarization treatment is performed. This case is also regarded as being “level or substantially level” in this specification and the like. For example, the expression “level or substantially level” also includes the case where two layers (here, given as a first layer and a second layer) whose levels with respect to the reference surface are different from each other are provided to have a difference between the top-surface level of the first layer and the top-surface level of the second layer of less than or equal to 20 nm.

Note that in this specification and the like, the expression “end portions are aligned or substantially aligned” means that at least outlines of stacked layers partly overlap with each other in a top view. For example, the case of processing the upper layer and the lower layer with use of the same mask pattern or mask patterns that are partly the same in a manufacturing process of a semiconductor device is included. However, in some cases, the outlines do not exactly overlap with each other and the outline of the upper layer is positioned inward from the outline of the lower layer or the outline of the upper layer is positioned outward from the outline of the lower layer. This case is also described with the expression “end portions are aligned or substantially aligned” in this specification and the like.

Note that in this specification and the like, for example, the terms “identical”, “the same”, “equal”, “uniform”, and the like (including synonyms of these words) used in describing calculation values and measurement values or in describing objects, methods, events, and the like that can be converted into calculation values or measurement values, allow for a margin of error of ±20 % unless otherwise specified.

In this specification and the like, an impurity in a semiconductor refers to a component other than a main component of a semiconductor, for example. For example, an element with a concentration of lower than 0.1 atomic % is an impurity. When an impurity is contained in a semiconductor, for example, the density of defect states in a semiconductor is increased, carrier mobility is decreased, or crystallinity is decreased in some cases. In the case where the semiconductor is an oxide semiconductor, examples of an impurity that changes the characteristics of the semiconductor include Group 1 elements, Group 2 elements, Group 13 elements, Group 14 elements, Group 15 elements, or transition metals other than the main components of the oxide semiconductor. Specific examples include hydrogen (included also in water), lithium, sodium, silicon, boron, phosphorus, carbon, and nitrogen. In addition, oxygen vacancies (also referred to as Vo) are formed in an oxide semiconductor in some cases by entry of impurities, for example.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like, for example. For example, in the case where a metal oxide is used in a semiconductor including a channel formation region of a transistor, the metal oxide is referred to as an oxide semiconductor in some cases. That is, when a metal oxide is used as a material that can be used for a channel formation region of a transistor that has at least one of an amplifying function, a rectifying function, and a switching function, the metal oxide can be referred to as a metal oxide semiconductor. In addition, the term “OS transistor” can also be referred to as a transistor containing a metal oxide or an oxide semiconductor.

In this specification and the like, a metal oxide containing nitrogen is also collectively referred to as a metal oxide in some cases. A metal oxide containing nitrogen may be referred to as a metal oxynitride.

In the drawings and the like in this specification, arrows indicating the X direction, the Y direction, and the Z direction are illustrated in some cases. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction”in some cases.

### REFERENCE NUMERALS

110: register, 120: scan flip-flop, 121: selector, 122: flip-flop, 130: data retention circuit, 131: memory circuit, 132: transistor, 133: transistor, 134: transistor, 135: capacitor, 136: capacitor, 20: element layer, 30: element layer, 30a: element layer, 30b: element layer, BK: signal, RE: signal, SE: signal, CLK: signal, D: terminal, SD: terminal, Q: terminal, SD_IN: terminal, Df: input terminal, Qf: output terminal, CL: wiring, SN: node, T1: time, T2: time, T3: time, T4: time, T5: time, T6: time, T7: time, T8: time, D1: data, D2: data, D3: data, D4: data, D5: data, D6: data, D7: data, D8: data, 100: arithmetic device, 101: control portion, 102: CPU core, 103: register portion, 105: register bank, 106: general register, Ta: time, Tb: time, Tc: time, 550: transistor, 37: transistor, 38: capacitor, 35: via hole, 36: via hole, 32: memory cell, 33: functional element, 311: substrate, 316: conductor, 315: insulator, 313: semiconductor region, 314a: low-resistance region, 314b: low-resistance region, 320: insulator, 322: insulator, 324: insulator, 326: insulator, 328: conductor, 330: conductor, 350: insulator, 352: insulator, 354: insulator, 356: conductor, 440: insulator, 410: conductor, 480: insulator, 280: insulator, 283: insulator, 290: opening, 490: opening, 415: conductor, 430: insulator, 420: conductor, 240: conductor, 230: oxide semiconductor, 250: insulator, 260: conductor, 230i: region, 230na: region, 230nb: region, 34: functional element, 39: connection portion, 431: insulator

1. A semiconductor device comprising:
a flip-flop circuit; and
a memory circuit,
wherein the memory circuit comprises:
a first transistor;
a second transistor;
a first capacitor;
a second capacitor;
a substrate comprising a first plane;
a first insulator over the substrate, the first insulator comprising a first opening and a second opening; and
a second insulator over the first insulator, the second insulator comprising a third opening and a fourth opening,
wherein one of a source and a drain of the first transistor is electrically connected to one of a source and a drain of the second transistor, a first terminal of the first capacitor, and a first terminal of the second capacitor,
wherein the other of the source and the drain of the first transistor is electrically connected to an output terminal of the flip-flop circuit,
wherein the other of the source and the drain of the second transistor is electrically connected to an input terminal of the flip-flop circuit,
wherein the first opening, the second opening, the third opening, and the fourth opening extend in a direction perpendicular to the first plane of the substrate,
wherein the flip-flop circuit is provided over the substrate,
wherein at the first capacitor is partly provided in the first opening
wherein the second capacitor is partly provided in the second opening,
wherein the first transistor is partly provided in the third opening, and
wherein the second transistor is partly provided in the fourth opening.

2. The semiconductor device according to claim 1,
wherein a dielectric layer of the first capacitor is partly provided along a sidewall of the first opening, and
wherein a semiconductor layer comprising a channel formation region of the first transistor is partly provided along a sidewall of the third opening.

3. The semiconductor device according to claim 2, wherein the semiconductor layer comprises an oxide semiconductor.

4. An arithmetic device comprising:
the semiconductor device according to claim 1; and
a control portion,
wherein the control portion is configured to generate a signal for controlling the semiconductor device,
wherein the semiconductor device is configured to save data retained in the flip-flop circuit in the memory circuit by controlling a conduction state or a non-conduction state of the first transistor, and
wherein the semiconductor device is configured to load data retained in the memory circuit into the flip-flop circuit by controlling a conduction state or a non-conduction state of the second transistor.

5. The arithmetic device according to claim 4,
wherein the semiconductor device comprises a plurality of the memory circuits, and
wherein, when tasks are switched, the semiconductor device is configured to save first data retained in the flip-flop circuit in any one of the plurality of the memory circuits and to load second data retained in any one of the plurality of the memory circuits into the flip-flop circuit.

6. A semiconductor device comprising:
a substrate;
a first insulator over the substrate, the first insulator comprising a first opening and a second opening;
a second insulator over the first insulator, the second insulator comprising a third opening and a fourth opening;
a flip-flop circuit over the substrate; and
a memory circuit over the flip-flop circuit,
wherein the memory circuit comprises:
a first transistor;
a second transistor;
a first capacitor; and
a second capacitor,
wherein one of a source and a drain of the first transistor is electrically connected to one of a source and a drain of the second transistor, a first terminal of the first capacitor, and a first terminal of the second capacitor,
wherein the other of the source and the drain of the first transistor is electrically connected to an output terminal of the flip-flop circuit,
wherein the other of the source and the drain of the second transistor is electrically connected to an input terminal of the flip-flop circuit,
wherein the first capacitor is provided in the first opening,
wherein the second capacitor is provided in the second opening,
wherein the first transistor is provided in the third opening, and
wherein the second transistor is provided in the fourth opening.
